(19) United States
(12) Patent Application Publication
(10) Pub. No.: US 2010/0317183 A1
(43) Pub. Date: Dec. 16, 2010

(54) METHOD FOR FABRICATING SEMICONDUCTOR MEMORY DEVICE

(76) Inventors: Koji YOSHIDA, Niigata (JP); Keita Takahashi, Nara (JP)

Correspondence Address: MCDERMOTT WILL & EMERY LLP, 600 13TH STREET, NW, WASHINGTON, DC, 20005-3096, US

(21) Appl. No.: 12/752,740

(22) Filed: Apr. 1, 2010

(30) Foreign Application Priority Data
Jun. 16, 2009 (JP) 2009-143496

(51) Int. Cl. H01L 21/28

(52) U.S. Cl. 438/591; 257/E21.21

(57) ABSTRACT

By removing an interlayer insulating film from a memory cell region in which a plurality of bit line diffusion layers and a plurality of word lines are formed, a trench which exposes the plurality of word lines and the sidewall insulating film is formed on the memory cell region. Thereafter, an ultraviolet light blocking film is formed on the exposed word lines and sidewall insulating film to fill the trench. Here, in the step of forming the trench, the trench is formed so that an end of the trench in a direction in which the bit line diffusion layers are extended is located on a word line located at an outermost portion of the memory cell region.

### CROSS-REFERENCE TO RELATED APPLICATION

This application claims priority to Japanese Patent Application No. 2009-143496 filed on Jun. 16, 2009, the disclosure of which including the specification, the drawings, and the claims is hereby incorporated by reference in its entirety.

### BACKGROUND

The present disclosure relates to methods for fabricating semiconductor memory devices, and more particularly, to methods for fabricating non-volatile semiconductor memory devices.

In recent years, localized-charge-trapping based metal oxide nitride oxide semiconductor (MONOS) memory devices which have a virtual ground array and locally trap charge have been proposed as non-volatile semiconductor memory devices with higher packaging density and lower cost.

However, in localized-charge-trapping based MONOS memory devices, ultraviolet light occurring during fabrication causes charge to be trapped in a multilayer film (ONO insulating film) which is a gate insulating film including a lower silicon oxide film, a silicon nitride film, and an upper silicon oxide film, leading to threshold voltage fluctuations. Therefore, it is important to reduce or prevent the influence of ultraviolet light occurring during fabrication.

Semiconductor memory devices which include an ultraviolet light blocking film so as to reduce or prevent the influence of ultraviolet light have been proposed in, for example, U.S. Pat. No. 6,774,432 and the like.

An example of such conventional semiconductor memory devices will be described with reference to FIG. 26. FIG. 26 shows a plan view of the structure of the conventional semiconductor memory device.

As shown in FIG. 26, contact diffusion layers 113 are formed in a semiconductor substrate, and contact electrodes 112 are formed on the respective contact diffusion layers 113. An isolation insulating film 103 is formed between any two adjacent to each other in an X-direction of the contact diffusion layers 113. Note that bit line diffusion layers 105 connected to the respective contact diffusion layers 113 are extended in a Y-direction, although not shown. A first gate electrode 107a, a second gate electrode 107b, and a third gate electrode 107c are formed on the semiconductor substrate, extending in parallel with the X-direction and intersecting the bit line diffusion layers 105. Here, the first gate electrode 107a is a dummy word line. A sidewall insulating film 108 is formed on side surfaces of each of the first, second, and third gate electrodes 107a, 107b, and 107c. In other words, the sidewall insulating film 108 is embedded between the first, second, and third gate electrodes 107a, 107b, and 107c.

Next, a method for fabricating the conventional semiconductor memory device will be described with reference to FIGS. 27A-34C. Those figures having a number followed by the capital letter “A” show cross-sectional structures of the device as viewed along line X11-X11 of FIG. 26 in the order in which the device is fabricated. Those figures having a number followed by the capital letter “B” show cross-sectional structures of the device as viewed along line Y11-Y11 of FIG. 26 in the order in which the device is fabricated. Those figures having a number followed by the capital letter “C” show cross-sectional structures of the device as viewed along line Y12-Y12 of FIG. 26 in the order in which the device is fabricated.

Initially, as shown in FIGS. 27A-27C, the isolation insulating film 103 is formed in an upper portion of the semiconductor substrate 101 using a trench method, and a P-type well 102 is formed in an upper portion of the semiconductor substrate 101 using an ion implantation method with a P-type well formation mask. An ONO insulating film 104 is formed on the P-type well 102 and the isolation insulating film 103, and a bit line formation mask 114 is formed on the ONO insulating film 104.

Next, as shown in FIGS. 28A-28C, the ONO insulating film 104 is selectively removed by etching using the mask 114. Thereafter, the bit line diffusion layers 105 are formed by ion implantation through a region in an upper portion of the P-type well 102 from which the ONO insulating film 104 has been removed. Thereafter, a bit line insulating film 106 is formed by performing thermal oxidation with respect to surfaces of the bit line diffusion layers 105. Thereafter, a conductive film 107A is formed on a remaining portion of the ONO insulating film 104 and the bit line insulating film 106.

Next, as shown in FIGS. 29A-29C, the conductive film 107A is selectively removed using a gate electrode formation mask to form the first, second, and third gate electrodes 107a, 107b, and 107c, which are word lines extending across a plurality of memory cells.

Next, as shown in FIGS. 30A-30C, an insulating film which is to be a sidewall insulating film 108 is deposited on the P-type well 102, the isolation insulating film 103, the ONO insulating film 104, and the bit line insulating film 106. Thereafter, the deposited insulating film is removed by anisotropic etching, leaving a portion thereof on side surfaces of the first, second, and third gate electrodes 107a, 107b, and 107c, thereby forming the sidewall insulating film 108. In this case, portions of the bit line insulating film 106 and the ONO insulating film 104 are also etched into the shape of a sidewall. The contact diffusion layers 113 are formed in regions of an upper portion of the P-type well 102 in which the bit line diffusion layers 105 are not formed, by ion implantation using, as a mask, the first gate electrode 107a and the sidewall insulating film 108 on a side surface opposite to the second gate electrode 107b of the first gate electrode 107a. Here, the contact diffusion layers 113 are formed to be connected to the respective bit line diffusion layers 105.

Next, as shown in FIG. 31A-31C, a first interlayer insulating film 109 and an ultraviolet light blocking film 110 are successively formed on the isolation insulating film 103, the first, second, and third gate electrodes 107a, 107b, and 107c, the sidewall insulating film 108, and the contact diffusion layers 113.

Next, as shown in FIGS. 32A-32C, portions of the ultraviolet light blocking film 110 are selectively removed to form openings using a mask for removing the ultraviolet light blocking film 110 in regions in which the contact electrodes 112 will be subsequently formed.

Next, as shown in FIGS. 33A-33C, a second interlayer insulating film 111 is deposited on the first interlayer insulating film 109 and the ultraviolet light blocking film 110, and a surface of the second interlayer insulating film 111 is planarized by chemical mechanical polishing (CMP).

Next, as shown in FIG. 34, contact holes which penetrate predetermined regions of the first and second interlayer insulating films 109 and 111 to expose the contact diffusion layers 113, are formed using a contact electrode formation mask in regions in which the contact electrodes 112 will be subsequently formed. The contact holes are filled with tungsten by chemical vapor deposition (CVD), and the tungsten on the second interlayer insulating film 111 is removed by CMP, thereby forming the contact electrodes 112.

Thereafter, the semiconductor memory device is completed by a wiring step following formation of a first-layer metal electrode. These steps are performed using commonly used techniques and therefore will not be described herein.

By the aforementioned fabrication, the memory cell including the ONO insulating film 104 which serves as a charge trapping film can be protected from ultraviolet light after the deposition of the ultraviolet light blocking film 110. Therefore, the memory cell can have a structure which reduces or prevents the influence of ultraviolet light occurring in the subsequent steps.

### SUMMARY

However, the conventional art has a problem that, as shown in FIG. 35, the initial threshold voltage of the memory cell is increased by the influence of ultraviolet light 115 entering in a horizontal direction through the opening of the ultraviolet light blocking film 110 in the step of forming the opening in the ultraviolet light blocking film 110 and the following steps. Therefore, the initial threshold voltage of the memory cell in the vicinity of the contact hole is increased. To alleviate the problem, it is necessary to increase a size 116 of a protrusion portion of the ultraviolet light blocking film 110 shown in FIG. 35. However, the increase in the size 116 leads to an increase in the area of the contact formation region.

In view of the aforementioned problem, the detailed description describes implementations of reduction or prevention of the influence of ultraviolet light entering in a horizontal direction through the opening of the ultraviolet light blocking film after the formation of the opening, whereby the initial threshold voltage of the memory cell and the area of the contact formation area are reduced or prevented.

In an example method for fabricating a semiconductor memory device according to the present disclosure, a trench is formed in a first interlayer insulating film on a memory cell region so that an end portion of the trench is located on a word line located an outermost portion of a memory cell region, and an ultraviolet light blocking film is formed in the trench.

The method includes the steps of (a) forming a charge trapping film on a semiconductor substrate and removing a portion of the charge trapping film to form a plurality of openings which expose the semiconductor substrate, (b) forming a plurality of bit line diffusion layers extending in a predetermined direction in parallel with each other, on the exposed semiconductor substrate, (c) forming a plurality of word lines extending in parallel with each other and intersecting each of the plurality of bit line diffusion layers, on the charge trapping film and the plurality of bit line diffusion layers, (d) forming a sidewall insulating film on side surfaces of the plurality of word lines to be embedded between any adjacent two of the plurality of word lines, (e) forming a first interlayer insulating film to cover the charge trapping film, each of the plurality of bit line diffusion layers, each of the plurality of word lines, and the sidewall insulating film, (f) forming a trench to expose the plurality of word lines and the sidewall insulating film by removing the first interlayer insulating film on a memory cell region in which the plurality of bit line diffusion layers and the plurality of word lines are formed, and (g) forming an ultraviolet light blocking film on the plurality of word lines and the sidewall insulating film to fill the trench. In step (f), the trench is formed so that an end of the trench in a direction in which the bit line diffusion layers are extended is located on the word line which is located at an outermost portion of the memory cell region.

According to the example method of the present disclosure, it is possible to eliminate a protrusion portion of the ultraviolet light blocking film which extends into the contact formation region, and it is possible to reduce or prevent ultraviolet light which enters the ultraviolet light blocking film and reaches an ONO insulating film which is to be a charge trapping film of a memory cell. As a result, the area of a contact region can be reduced, and in addition, the increase in the initial threshold voltage of the memory cell can be reduced or prevented, whereby a stable memory characteristic can be obtained.

The method may further include the steps of (d1) between steps (d) and (e), forming a plurality of contact diffusion layers connected to the respective bit line diffusion layers, in regions of an upper portion of the semiconductor substrate extending from the respective bit line diffusion layers, using, as a mask, the word line and the sidewall insulating film located at an outermost portion of the memory cell region, (h) after step (g), forming a second interlayer insulating film to cover the first interlayer insulating film and the ultraviolet light blocking film, and (i) after step (h), forming, on the respective contact diffusion layers, contact electrodes which penetrate the second interlayer insulating film and the first interlayer insulating film to connect to the respective contact diffusion layers.

The method may further include the step of (f1) between steps (f) and (g), forming an insulating film on a bottom surface and a sidewall of the trench. In step (g), the ultraviolet light blocking film may be formed on the insulating film.

The method may further include the step of (g1) after step (g), forming a third interlayer insulating film on the ultraviolet light blocking film. The third interlayer insulating film may be formed to fill the trench.

The method may further include the steps of (d1) between steps (d) and (e), forming a plurality of contact diffusion layers connected to the respective bit line diffusion layers, in regions of an upper portion of the semiconductor substrate extending from the respective bit line diffusion layers, using, as a mask, the word line and the sidewall insulating film located at an outermost portion of the memory cell region, (h1) after step (g1), forming a second interlayer insulating film to cover the first interlayer insulating film, the ultraviolet light blocking film, and the third interlayer insulating film, and (i) after step (h1), forming, on the respective contact diffusion layers, contact electrodes which penetrate the second interlayer insulating film and the first interlayer insulating film to connect to the respective contact diffusion layers.

The method may further include the step of (f1) between steps (f) and (g), forming an insulating film on a bottom surface and a sidewall of the trench. In step (g), the ultraviolet light blocking film may be formed on the insulating film.

In the method, the word line located at the outermost portion of the memory cell region may be a dummy word line.

In the method, the insulating film may be a monolayer or multilayer film including one or at least two selected from a silicon oxide film, a silicon nitride film, a silicon carbide film, a silicon carbon nitride film, and a silicon oxycarbide film.

In the method, the insulating film may have a thickness of 5 nm or more and 50 nm or less.

In the method, the ultraviolet light blocking film may be a monolayer or multilayer film including one or at least two selected from a silicon film, a silicon oxide film, a silicon nitride film, a silicon carbide film, a silicon carbon nitride film, a silicon oxycarbide film, a titanium film, a titanium nitride film, an aluminum film, a copper film, and a tungsten film.

### BRIEF DESCRIPTION OF THE DRAWINGS

FIG. 1 is a plan view showing a semiconductor memory device according to a first illustrative embodiment.

FIG. 2 is a cross-sectional view of the semiconductor memory device of the first illustrative embodiment, taken along line X1-X1 of FIG. 1.

FIG. 3 is a cross-sectional view of the semiconductor memory device of the first illustrative embodiment, taken along line X2-X2 of FIG. 1.

FIG. 4 is a cross-sectional view of the semiconductor memory device of the first illustrative embodiment, taken along line X3-X3 of FIG. 1.

FIG. 5 is a cross-sectional view of the semiconductor memory device of the first illustrative embodiment, taken along line Y1-Y1 of FIG. 1.

FIG. 6 is a cross-sectional view of the semiconductor memory device of the first illustrative embodiment, taken along line Y2-Y2 of FIG. 1.

FIG. 7A is a cross-sectional view showing a step in a method for fabricating the semiconductor memory device of the first illustrative embodiment, taken along line X1-X1 of FIG. 1.

FIG. 7B is a cross-sectional view showing the step in the method for fabricating the semiconductor memory device of the first illustrative embodiment, taken along line Y1-Y1 of FIG. 1.

FIG. 7C is a cross-sectional view showing the step in the method for fabricating the semiconductor memory device of the first illustrative embodiment, taken along line Y2-Y2 of FIG. 1.

FIG. 8A is a cross-sectional view showing a step in the method for fabricating the semiconductor memory device of the first illustrative embodiment, taken along line X1-X1 of FIG. 1.

FIG. 8B is a cross-sectional view showing the step in the method for fabricating the semiconductor memory device of the first illustrative embodiment, taken along line Y1-Y1 of FIG. 1.

FIG. 8C is a cross-sectional view showing the step in the method for fabricating the semiconductor memory device of the first illustrative embodiment, taken along line Y2-Y2 of FIG. 1.

FIG. 9A is a cross-sectional view showing a step in the method for fabricating the semiconductor memory device of the first illustrative embodiment, taken along line X1-X1 of FIG. 1.

FIG. 9B is a cross-sectional view showing the step in the method for fabricating the semiconductor memory device of the first illustrative embodiment, taken along line Y1-Y1 of FIG. 1.

FIG. 9C is a cross-sectional view showing the step in the method for fabricating the semiconductor memory device of the first illustrative embodiment, taken along line Y2-Y2 of FIG. 1.

FIG. 10A is a cross-sectional view showing a step in the method for fabricating the semiconductor memory device of the first illustrative embodiment, taken along line X1-X1 of FIG. 1.

FIG. 10B is a cross-sectional view showing the step in the method for fabricating the semiconductor memory device of the first illustrative embodiment, taken along line Y1-Y1 of FIG. 1.

FIG. 10C is a cross-sectional view showing the step in the method for fabricating the semiconductor memory device of the first illustrative embodiment, taken along line Y2-Y2 of FIG. 1.

FIG. 11A is a cross-sectional view showing a step in the method for fabricating the semiconductor memory device of the first illustrative embodiment, taken along line X1-X1 of FIG. 1.

FIG. 11B is a cross-sectional view showing the step in the method for fabricating the semiconductor memory device of the first illustrative embodiment, taken along line Y1-Y1 of FIG. 1.

FIG. 11C is a cross-sectional view showing the step in the method for fabricating the semiconductor memory device of the first illustrative embodiment, taken along line Y2-Y2 of FIG. 1.

FIG. 12A is a cross-sectional view showing a step in the method for fabricating the semiconductor memory device of the first illustrative embodiment, taken along line X1-X1 of FIG. 1.

FIG. 12B is a cross-sectional view showing the step in the method for fabricating the semiconductor memory device of the first illustrative embodiment, taken along line Y1-Y1 of FIG. 1.

FIG. 12C is a cross-sectional view showing the step in the method for fabricating the semiconductor memory device of the first illustrative embodiment, taken along line Y2-Y2 of FIG. 1.

FIG. 13A is a cross-sectional view showing a step in the method for fabricating the semiconductor memory device of the first illustrative embodiment, taken along line X1-X1 of FIG. 1.

FIG. 13B is a cross-sectional view showing the step in the method for fabricating the semiconductor memory device of the first illustrative embodiment, taken along line Y1-Y1 of FIG. 1.

FIG. 13C is a cross-sectional view showing the step in the method for fabricating the semiconductor memory device of the first illustrative embodiment, taken along line Y2-Y2 of FIG. 1.

FIG. 14A is a cross-sectional view showing a step in the method for fabricating the semiconductor memory device of the first illustrative embodiment, taken along line X1-X1 of FIG. 1.

FIG. 14B is a cross-sectional view showing the step in the method for fabricating the semiconductor memory device of the first illustrative embodiment, taken along line Y1-Y1 of FIG. 1.

FIG. 14C is a cross-sectional view showing the step in the method for fabricating the semiconductor memory device of the first illustrative embodiment, taken along line Y2-Y2 of FIG. 1.

FIG. 15A is a cross-sectional view showing a step in the method for fabricating the semiconductor memory device of the first illustrative embodiment, taken along line X1-X1 of FIG. 1.

FIG. 15B is a cross-sectional view showing the step in the method for fabricating the semiconductor memory device of the first illustrative embodiment, taken along line Y1-Y1 of FIG. 1.

FIG. 15C is a cross-sectional view showing the step in the method for fabricating the semiconductor memory device of the first illustrative embodiment, taken along line Y2-Y2 of FIG. 1.

FIG. 16A is a cross-sectional view showing a step in the method for fabricating the semiconductor memory device of the first illustrative embodiment, taken along line X1-X1 of FIG. 1.

FIG. 16B is a cross-sectional view showing the step in the method for fabricating the semiconductor memory device of the first illustrative embodiment, taken along line Y1-Y1 of FIG. 1.

FIG. 16C is a cross-sectional view showing the step in the method for fabricating the semiconductor memory device of the first illustrative embodiment, taken along line Y2-Y2 of FIG. 1.

FIG. 17A is a cross-sectional view showing a step in a method for fabricating a semiconductor memory device according to a second illustrative embodiment, taken along line X1-X1 of FIG. 1.

FIG. 17B is a cross-sectional view showing the step in the method for fabricating the semiconductor memory device of the second illustrative embodiment, taken along line Y1-Y1 of FIG. 1.

FIG. 17C is a cross-sectional view showing the step in the method for fabricating the semiconductor memory device of the second illustrative embodiment, taken along line Y2-Y2 of FIG. 1.

FIG. 18A is a cross-sectional view showing a step in the method for fabricating the semiconductor memory device of the second illustrative embodiment, taken along line X1-X1 of FIG. 1.

FIG. 18B is a cross-sectional view showing the step in the method for fabricating the semiconductor memory device of the second illustrative embodiment, taken along line Y1-Y1 of FIG. 1.

FIG. 18C is a cross-sectional view showing the step in the method for fabricating the semiconductor memory device of the second illustrative embodiment, taken along line Y2-Y2 of FIG. 1.

FIG. 19A is a cross-sectional view showing a step in the method for fabricating the semiconductor memory device of the second illustrative embodiment, taken along line X1-X1 of FIG. 1.

FIG. 19B is a cross-sectional view showing the step in the method for fabricating the semiconductor memory device of the second illustrative embodiment, taken along line Y1-Y1 of FIG. 1.

FIG. 19C is a cross-sectional view showing the step in the method for fabricating the semiconductor memory device of the second illustrative embodiment, taken along line Y2-Y2 of FIG. 1.

FIG. 20A is a cross-sectional view showing a step in the method for fabricating the semiconductor memory device of the second illustrative embodiment, taken along line X1-X1 of FIG. 1.

FIG. 20B is a cross-sectional view showing the step in the method for fabricating the semiconductor memory device of the second illustrative embodiment, taken along line Y1-Y1 of FIG. 1.

FIG. 20C is a cross-sectional view showing the step in the method for fabricating the semiconductor memory device of the second illustrative embodiment, taken along line Y2-Y2 of FIG. 1.

FIG. 21 is a diagram showing an advantage of the semiconductor memory device fabrication method of the second illustrative embodiment over that of the first illustrative embodiment.

FIG. 22 is a diagram showing an advantage of the semiconductor memory device fabrication method of the second illustrative embodiment over that of the first illustrative embodiment.

FIG. 23 is a cross-sectional view of a semiconductor memory device according to a first variation of the first illustrative embodiment.

FIG. 24 is a cross-sectional view of a semiconductor memory device according to a variation of the second illustrative embodiment.

FIG. 25A is a cross-sectional view of a semiconductor memory device according to a second variation of the first illustrative embodiment, taken along line Y1-Y1 of FIG. 1.

FIG. 25B is a cross-sectional view of the semiconductor memory device of the second variation of the first illustrative embodiment, taken along line Y2-Y2 of FIG. 1.

FIG. 26 is a plan view showing a conventional semiconductor memory device.

FIG. 27A is a cross-sectional view showing a step in a method for fabricating the conventional semiconductor memory device, taken along line X11-X11 of FIG. 26.

FIG. 27B is a cross-sectional view showing the step in the method for fabricating the conventional semiconductor memory device, taken along line Y11-Y11 of FIG. 26.

FIG. 27C is a cross-sectional view showing the step in the method for fabricating the conventional semiconductor memory device, taken along line Y12-Y12 of FIG. 26.

FIG. 28A is a cross-sectional view showing a step in the method for fabricating the conventional semiconductor memory device, taken along line X11-X11 of FIG. 26.

FIG. 28B is a cross-sectional view showing the step in the method for fabricating the conventional semiconductor memory device, taken along line Y11-Y11 of FIG. 26.

FIG. 28C is a cross-sectional view showing the step in the method for fabricating the conventional semiconductor memory device, taken along line Y12-Y12 of FIG. 26.

FIG. 29A is a cross-sectional view showing a step in the method for fabricating the conventional semiconductor memory device, taken along line X11-X11 of FIG. 26.

FIG. 29B is a cross-sectional view showing the step in the method for fabricating the conventional semiconductor memory device, taken along line Y11-Y11 of FIG. 26.

FIG. 29C is a cross-sectional view showing the step in the method for fabricating the conventional semiconductor memory device, taken along line Y12-Y12 of FIG. 26.

FIG. 30A is a cross-sectional view showing a step in the method for fabricating the conventional semiconductor memory device, taken along line X11-X11 of FIG. 26.

FIG. 30B is a cross-sectional view showing the step in the method for fabricating the conventional semiconductor memory device, taken along line Y11-Y11 of FIG. 26.

FIG. 30C is a cross-sectional view showing the step in the method for fabricating the conventional semiconductor memory device, taken along line Y12-Y12 of FIG. 26.

FIG. 31A is a cross-sectional view showing a step in the method for fabricating the conventional semiconductor memory device, taken along line X11-X11 of FIG. 26.

FIG. 31B is a cross-sectional view showing the step in the method for fabricating the conventional semiconductor memory device, taken along line Y11-Y11 of FIG. 26.

FIG. 31C is a cross-sectional view showing the step in the method for fabricating the conventional semiconductor memory device, taken along line Y12-Y12 of FIG. 26.

FIG. 32A is a cross-sectional view showing a step in the method for fabricating the conventional semiconductor memory device, taken along line X11-X11 of FIG. 26.

FIG. 32B is a cross-sectional view showing the step in the method for fabricating the conventional semiconductor memory device, taken along line Y11-Y11 of FIG. 26.

FIG. 32C is a cross-sectional view showing the step in the method for fabricating the conventional semiconductor memory device, taken along line Y12-Y12 of FIG. 26.

FIG. 33A is a cross-sectional view showing a step in the method for fabricating the conventional semiconductor memory device, taken along line X11-X11 of FIG. 26.

FIG. 33B is a cross-sectional view showing the step in the method for fabricating the conventional semiconductor memory device, taken along line Y11-Y11 of FIG. 26.

FIG. 33C is a cross-sectional view showing the step in the method for fabricating the conventional semiconductor memory device, taken along line Y12-Y12 of FIG. 26.

FIG. 34A is a cross-sectional view showing a step in the method for fabricating the conventional semiconductor memory device, taken along line X11-X11 of FIG. 26.

FIG. 34B is a cross-sectional view showing the step in the method for fabricating the conventional semiconductor memory device, taken along line Y11-Y11 of FIG. 26.

FIG. 34C is a cross-sectional view showing the step in the method for fabricating the conventional semiconductor memory device, taken along line Y12-Y12 of FIG. 26.

FIG. 35 is a cross-sectional view showing a problem with the conventional semiconductor memory device.

### DETAILED DESCRIPTION

### First Illustrative Embodiment

A semiconductor memory device according to a first illustrative embodiment and a method for fabricating the semiconductor memory device will be described with reference to the accompanying drawings.

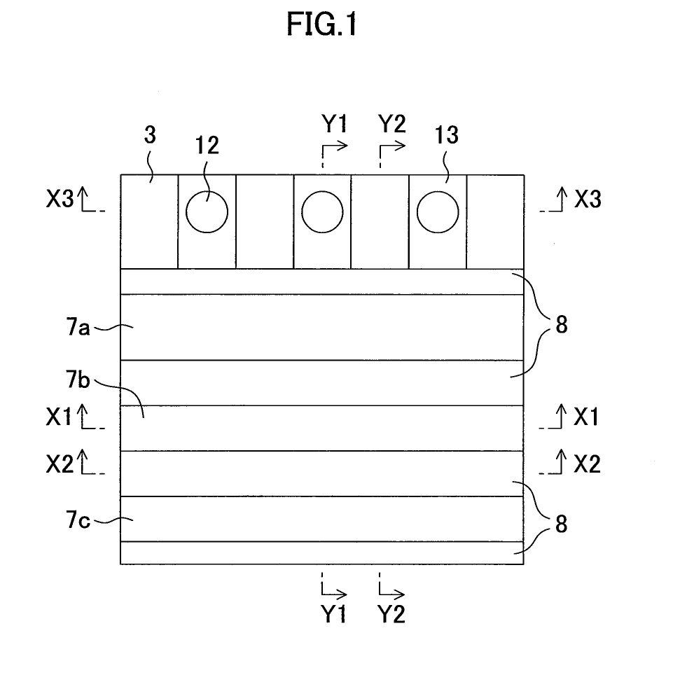

Firstly, a structure as viewed from the top of the semiconductor memory device of this illustrative embodiment will be described with reference to FIG. 1.

As shown in FIG. 1, contact diffusion layers 13 are formed in a semiconductor substrate, and contact electrodes 12 are formed on the respective contact diffusion layers 13. An isolation insulating film 3 is formed between any two adjacent to each other in an X-direction of the contact diffusion layers 13. Note that bit line diffusion layers 5 connected to the respective contact diffusion layers 13 are extended in the Y-direction, although not shown. A first gate electrode 7a, a second gate electrode 7b, and a third gate electrode 7c are formed on the semiconductor substrate, extending in parallel with the X-direction and intersecting the bit line diffusion layers 5. Here, the first gate electrode 7a is a dummy word line. A sidewall insulating film 8 is formed on side surfaces of each of the first, second, and third gate electrodes 7a, 7b, and 7c. In other words, the sidewall insulating film 8 is embedded between the first, second, and third gate electrodes 7a, 7b, and 7c.

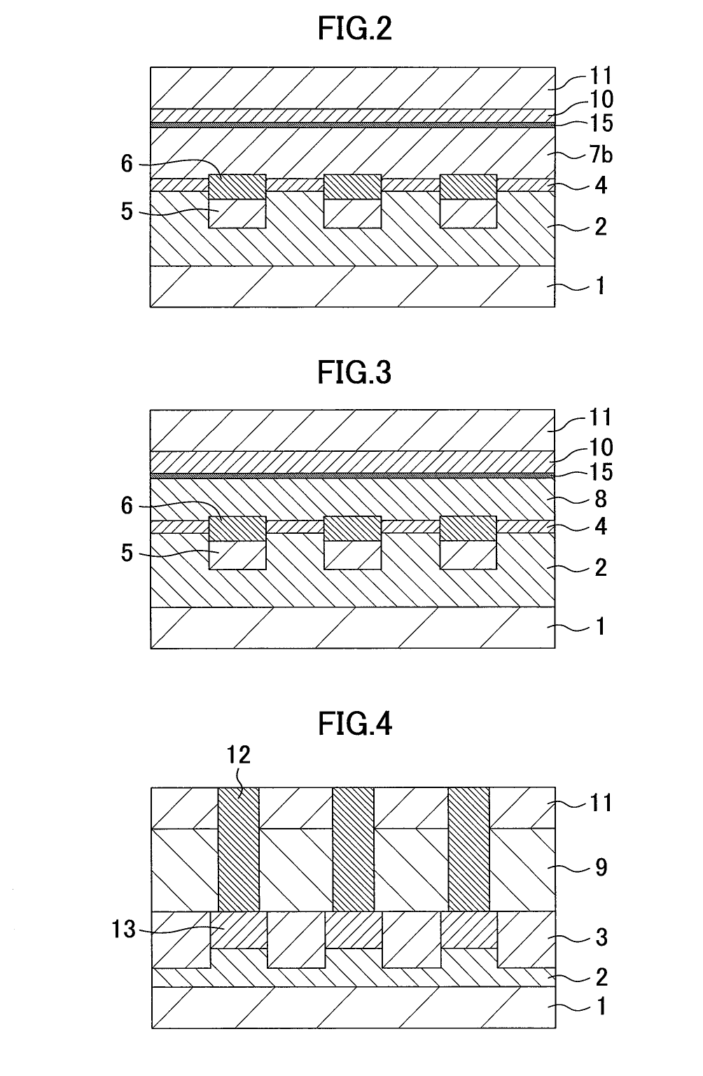

Next, cross-sectional structures of the semiconductor memory device of this illustrative embodiment as viewed along line X1-X1, line X2-X2, line X3-X3, line Y1-Y1, and line Y2-Y2 of FIG. 1, will be described with reference to FIGS. 2-6, respectively.

As shown in FIG. 2, in the cross-sectional structure as viewed along line X1-X1, a P-type well 2 is formed in an upper portion of the semiconductor substrate 1, and the bit line diffusion layers 5 are formed and separated from each other in an upper portion of the P-type well 2. A bit line insulating film 6 is formed on the bit line diffusion layers 5. An ONO insulating film 4 is formed on a region of the P-type well 2 in which the bit line insulating film 6 is not formed. The second gate electrode 7b, a liner insulating film 15, an ultraviolet light blocking film 10, and a second interlayer insulating film 11 are successively formed on the ONO insulating film 4 and the bit line insulating film 6.

As shown in FIG. 3, in the cross-sectional structure as viewed along line X2-X2, the P-type well 2 is formed in an upper portion of the semiconductor substrate 1, and the bit line diffusion layers 5 are formed and separated from each other in an upper portion of the P-type well 2. The bit line insulating film 6 is formed on the bit line diffusion layers 5, and the ONO insulating film 4 is formed on a region of the P-type well 2 in which the bit line insulating film 6 is not formed. The sidewall insulating film 8, the liner insulating film 15, the ultraviolet light blocking film 10, and the second interlayer insulating film 11 are successively formed on the ONO insulating film 4 and the bit line insulating film 6. Note that the sidewall insulating film 8 is typically a silicon nitride film or a silicon oxide film and has a thickness of about 70 nm.

As shown in FIG. 4, in the cross-sectional structure as viewed along line X3-X3, the P-type well 2 is formed in an upper portion of the semiconductor substrate 1, and the contact diffusion layers 13 are formed and separated from each other in an upper portion of the P-type well 2. The isolation insulating film 3 is formed on a region of the P-type well 2 in which the contact diffusion layers 13 are not formed. A first interlayer insulating film 9 and the second interlayer insulating film 11 are successively formed on the contact diffusion layers 13 and the isolation insulating film 3. The contact electrodes 12 which penetrate the first and second interlayer insulating films 9 and 11 to connect to the contact diffusion layers 13 are formed on the contact diffusion layers 13. In general, the bit line diffusion layers 5 and the contact diffusion layers 13 are made of arsenic alone or of arsenic and phosphorus. The isolation insulating film 3 is a silicon oxide film having a thickness of 400 nm which is formed by chemical vapor deposition (CVD). The contact electrodes 12 may be made of tungsten, and a titanium nitride film may be formed as a barrier film.

As shown in FIG. 5, in the cross-sectional structure as viewed along line Y1-Y1, the P-type well 2 is formed in an upper portion of the semiconductor substrate 1, and the bit line diffusion layers 5 and the contact diffusion layers 13 are formed in an upper portion of the P-type well 2 so that the contact diffusion layers 13 contact the respective bit line diffusion layers 5. The bit line insulating film 6 is formed on the bit line diffusion layers 5, and the first, second, and third gate electrodes 7a, 7b, and 7c are formed on the bit line insulating film 6. The sidewall insulating film 8 is formed on side surfaces of the first, second, and third gate electrodes 7a, 7b, and 7c. In other words, the sidewall insulating film 8 is embedded between the first, second, and third gate electrodes 7a, 7b, and 7c. The first interlayer insulating film 9 is formed on a portion of an upper surface farther away from the second gate electrode 7b of the first gate electrode 7a, the sidewall insulating film 8 provided on a side surface opposite to the second gate electrode 7b of the first gate electrode 7a, and the contact diffusion layers 13. The liner insulating film 15 and the ultraviolet light blocking film 10 are successively formed on regions of the first gate electrode 7a and the sidewall insulating film 8 in which the first interlayer insulating film 9 is not formed, and on the second gate electrode 7b and the third gate electrode 7c. The liner insulating film 15 is also formed on a side surface of the first interlayer insulating film 9 on the first gate electrode 7a. The second interlayer insulating film 11 is formed on the first interlayer insulating film 9, the ultraviolet light blocking film 10, and the liner insulating film 15. The contact electrodes 12 which penetrate the first interlayer insulating film 9 and the second interlayer insulating film 11 to contact to the respective contact diffusion layers 13 are formed on the respective contact diffusion layers 13. Here, because the contact diffusion layers 13 is formed by ion implantation using, as a mask, the first, second, and third gate electrodes 7a, 7b, and 7c, and the sidewall insulating film 8, the contact diffusion layers 13 are formed in a self-alignment manner with respect to the sidewall insulating film 8 on a side surface opposite to the second gate electrode 7b of the first gate electrode 7a. Note that, in some fabrication methods, the bit line diffusion layers 5 and the contact diffusion layers 13 are the same diffusion layer and are formed in the same step.

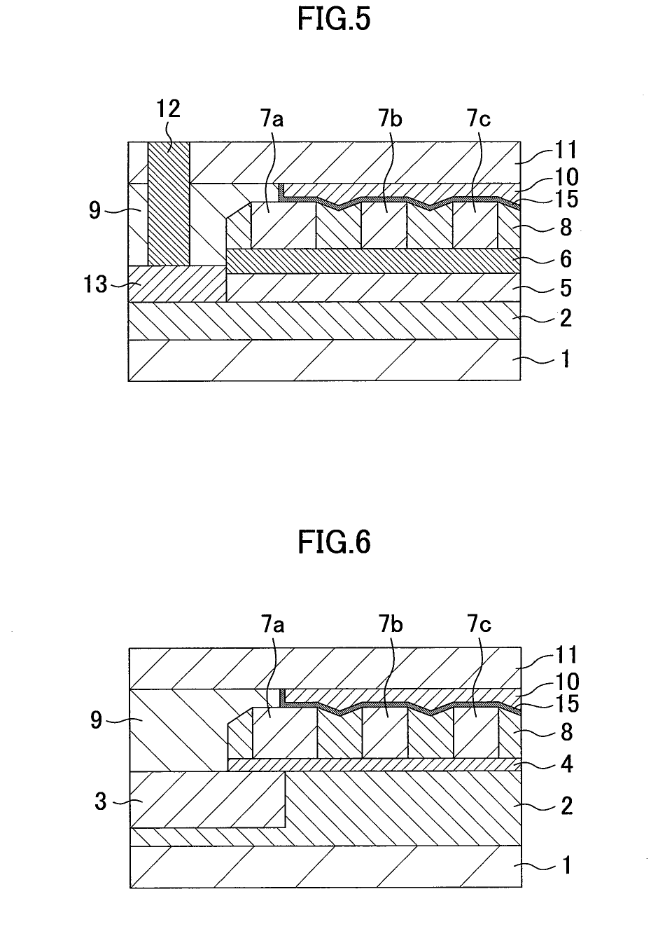

As shown in FIG. 6, in the cross-sectional structure as viewed along line Y2-Y2, the P-type well 2 is formed in an upper portion of the semiconductor substrate 1, the isolation insulating film 3 is formed in the P-type well 2, and the ONO insulating film 4 is formed on the P-type well 2 and a portion of the isolation insulating film 3. The first, second, and third gate electrodes 7a, 7b, and 7c are formed on the ONO insulating film 4. The sidewall insulating film 8 is formed on side surfaces of the first, second, and third gate electrodes 7a, 7b, and 7c. In other words, the sidewall insulating film 8 is embedded between the first, second, and third gate electrodes 7a, 7b, and 7c. The first interlayer insulating film 9 is formed on a portion of an upper surface farther away from the second gate electrode 7b of the first gate electrode 7a, the sidewall insulating film 8 provided on a side surface opposite to the second gate electrode 7b of the first gate electrode 7a, and the contact diffusion layers 13. The liner insulating film 15 and the ultraviolet light blocking film 10 are successively formed on regions of the first gate electrode 7a and the sidewall insulating film 8 in which the first interlayer insulating film 9 is not formed, and on the second gate electrode 7b and the third gate electrode 7c. The liner insulating film 15 is also formed on a side surface of the first interlayer insulating film 9 on the first gate electrode 7a. The second interlayer insulating film 11 is formed on the first interlayer insulating film 9, the ultraviolet light blocking film 10, and the liner insulating film 15.

In general, the bit line diffusion layers 5 and the contact diffusion layers 13 are made of arsenic alone or of arsenic and phosphorus, and the isolation insulating film 3 is a silicon oxide film having a thickness of 400 nm which is formed by CVD. The contact electrode 12 may be made of tungsten, and a titanium nitride film may be formed as a barrier film.

The bit line insulating film 6 is a silicon oxide film having a thickness of about 50 nm. The ONO insulating film 4 is a multilayer film including a silicon oxide film having a thickness of about 5 nm, a silicon nitride film having a thickness of about 5 nm, and a silicon oxide film having a thickness of about 10 nm which are stacked in this stated order, where the silicon oxide film having a thickness of about 5 nm is the lowest. The first, second, and third gate electrodes 7a, 7b, and 7c are made of N⁺-type polysilicon having a thickness of about 200 nm. The first interlayer insulating film 9 is a silicon oxide film having a thickness of about 500 nm which is formed by CVD, and the second interlayer insulating film 11 is a silicon oxide film having a thickness of about 300 nm which is formed by CVD.

The ultraviolet light blocking film 10 has a thickness of about 30-200 nm, and is a monolayer or multilayer film including one or at least two selected from silicon (Si) (including amorphous, polysilicon, and single crystal states, etc.), silicon oxide (SiO), silicon nitride (SiN), silicon carbide (SiC), silicon carbon nitride (SiCN), silicon oxycarbide (SiOC), titanium (Ti), titanium nitride (TiN), aluminum (Al), copper (Cu), and tungsten (W). Films made of SiO or the like containing Si do not have perfect light blocking capability. In such films, the capability of blocking ultraviolet light is enhanced with an increase in the composition ratio of Si, i.e., the light blocking capability is adjusted by changing a thickness or the like thereof. Note that a monolayer film made of Si has almost perfect light blocking capability if the monolayer film has a thickness of about 60 nm. The ultraviolet light blocking film 10 may be doped with phosphorus (P), or may not be doped with phosphorus (P) when higher insulation capability is desired. A metal conductor, such as Ti, TiN, Al, Cu, W or the like, may be used if the conductor is allowed to be used in terms of structure. In general, metal has high ultraviolet light blocking capability, and therefore, gold (Au), silver (Ag), platinum (Pt), or the like may be used. However, a metal film which is currently employed in commonly used semiconductor processes is illustrated herein.

Although, in FIG. 5, a lower end of the ultraviolet light blocking film 10 contacts the second gate electrode 7b and the third gate electrode 7c with the liner insulating film 15 being interposed therebetween, the liner insulating film 15 may be removed if the ultraviolet light blocking film 10 is an insulating film. The liner insulating film 15 preferably has a thickness of about 50 nm or less. This is because it is commonly considered that the wavelength of ultraviolet light which increases the threshold voltage of MONOS memory devices is about 250 nm, and the thickness of about 50 nm causes the influence of ultraviolet light on a memory cell to be small even if the diffraction and polarization of the light are taken into consideration. The liner insulating film 15 is a monolayer or multilayer film including one or at least two selected from SiO, SiN, SiC, SiCN, and SiOC.

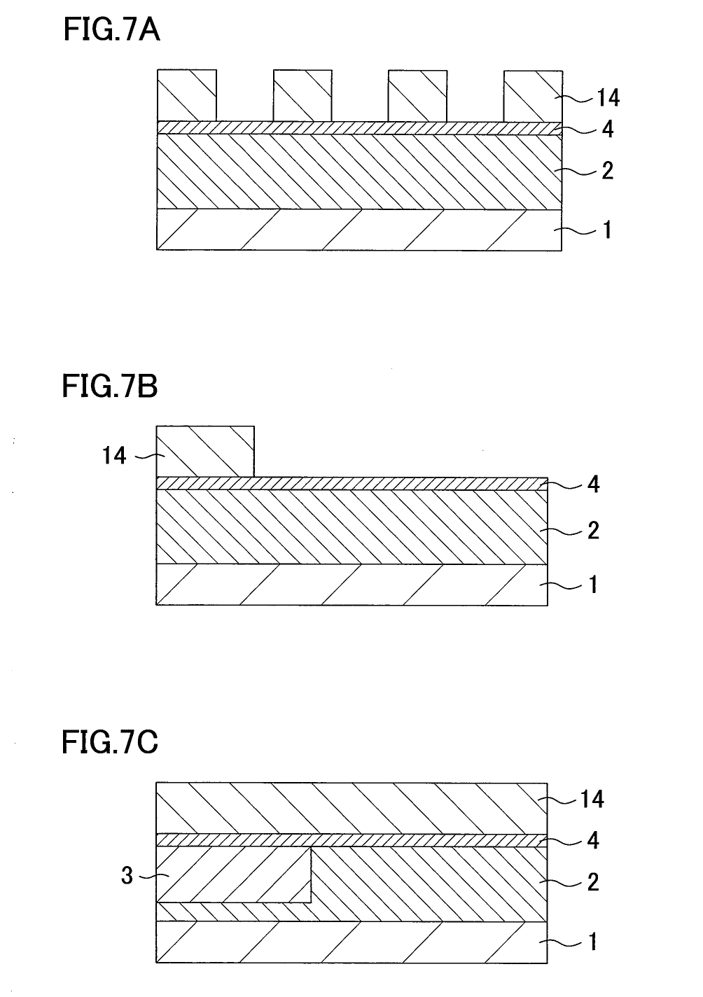

Next, a method for fabricating the semiconductor device of this illustrative embodiment will be described with reference to FIGS. 7A-16C. Those figures having a number followed by the capital letter “A” show cross-sectional structures of the device as viewed along line X1-X1 of FIG. 1 in the order in which the device is fabricated. Those figures having a number followed by the capital letter “B” show cross-sectional structures of the device as viewed along line Y1-Y1 of FIG. 1 in the order in which the device is fabricated. Those figures having a number followed by the capital letter “C” show cross-sectional structures of the device as viewed along line Y2-Y2 of FIG. 1 in the order in which the device is fabricated.

Initially, as shown in FIGS. 7A-7C, the isolation insulating film 3 is formed in an upper portion of the semiconductor substrate 1 by a trench method. Here, the isolation insulating film 3 is a silicon oxide film having a thickness of 400 nm which is formed by CVD. Thereafter, a P-type well formation mask is formed on the semiconductor substrate 1, the P-type well 2 is formed in an upper portion of the semiconductor substrate 1 by ion implantation using the mask, and thereafter, the P-type well formation mask is removed. Thereafter, the ONO insulating film 4 is formed on the P-type well 2 and the isolation insulating film 3, and a bit line formation mask 14 is formed on the ONO insulating film 4. The ONO insulating film 4 is a multilayer film including a silicon oxide film having a thickness of about 5 nm, a silicon nitride film having a thickness of about 5 nm, and a silicon oxide film having a thickness of about 10 nm which are stacked in this stated order, where the silicon oxide film having a thickness of about 5 nm is the lowest.

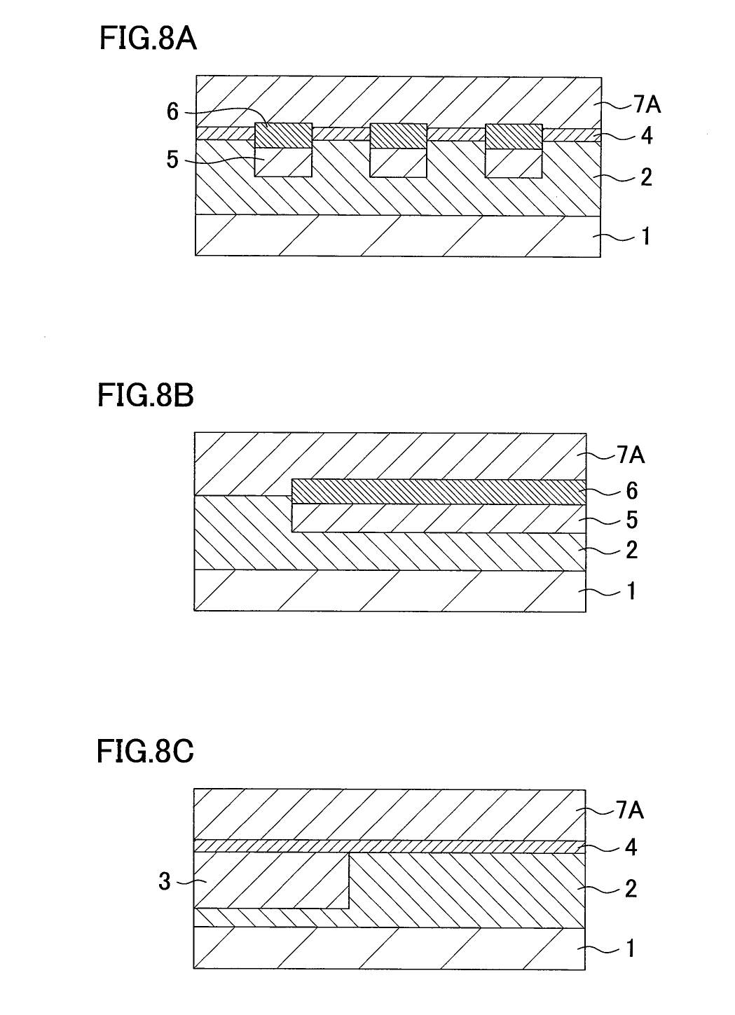

Next, as shown in FIGS. 8A-8C, the ONO insulating film 4 is selectively removed by etching using the mask 14, and thereafter, the bit line diffusion layers 5 are formed by ion implantation through regions of an upper portion of the P-type well 102 from which the ONO insulating film 4 has been removed. The ion implantation is performed using arsenic alone or using arsenic and phosphorus. Thereafter, the bit line insulating film 6 is formed by performing thermal oxidation with respect to surfaces of the bit line diffusion layers 5. Thereafter, a conductive film 7A made of N⁺-type polysilicon is formed on a remaining portion of the ONO insulating film 4 and the bit line insulating film 6.

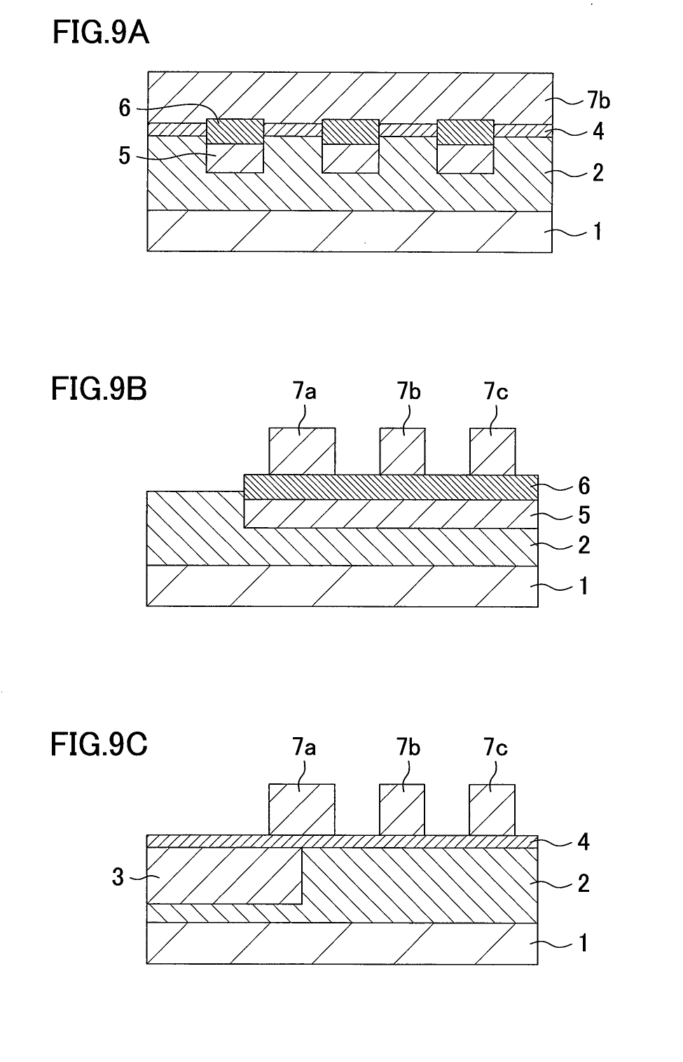

Next, as shown in FIGS. 9A-9C, the conductive film 7A is selectively removed using a gate electrode formation mask to form the first, second, and third gate electrodes 7a, 7b, and 7c having a thickness of about 200 nm, which are word lines extending across a plurality of memory cells. Here, the first gate electrode 7a is a dummy word line.

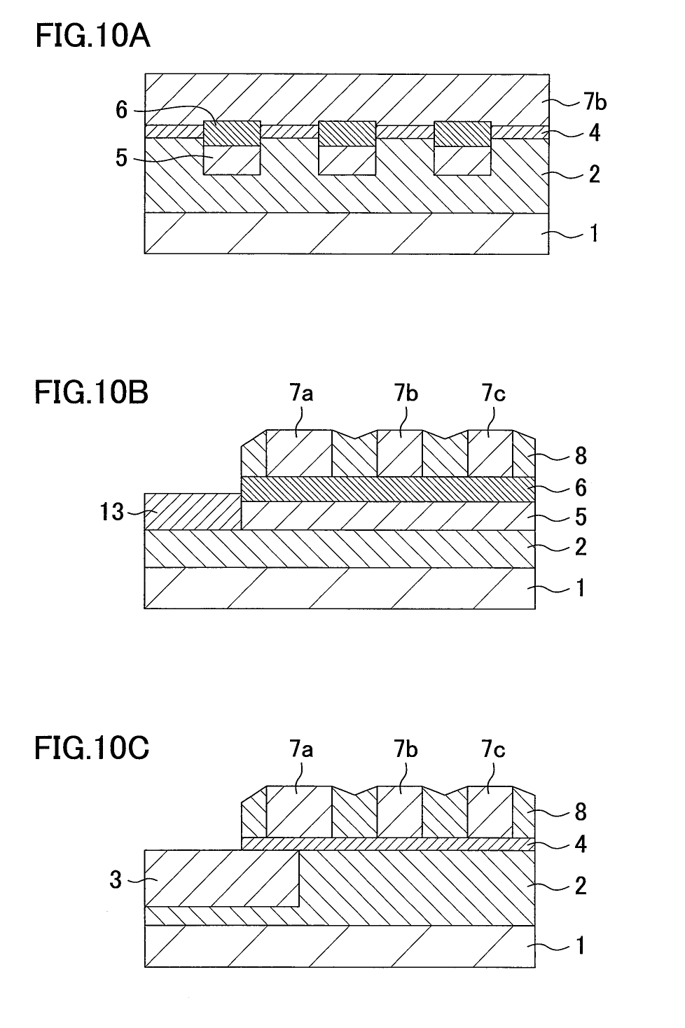

Next, as shown in FIGS. 10A-10C, an insulating film made of SiN which is to be the sidewall insulating film 8 is deposited on the P-type well 2, the isolation insulating film 3, the ONO insulating film 4, and the bit line insulating film 6. The insulating film may be made of SiO. Thereafter, the deposited insulating film is removed by anisotropic etching, leaving a portion thereof on side surfaces of the first, second, and third gate electrodes 7a, 7b, and 7c, thereby forming the sidewall insulating film 8 having a thickness of about 70 nm. In this case, portions of the bit line insulating film 6 and the ONO insulating film 4 are etched into the shape of a sidewall. The contact diffusion layers 13 are formed by performing ion implantation with respect to a region of an upper portion of the P-type well 2 in which the bit line diffusion layers 5 are not formed, using, as a mask, the first gate electrode 7a and the sidewall insulating film 8 on a side surface opposite to the second gate electrode 7b of the first gate electrode 7a. The ion implantation is performed using arsenic alone or using arsenic and phosphorus. Here, the contact diffusion layers 13 are formed to be connected to the respective bit line diffusion layers 5.

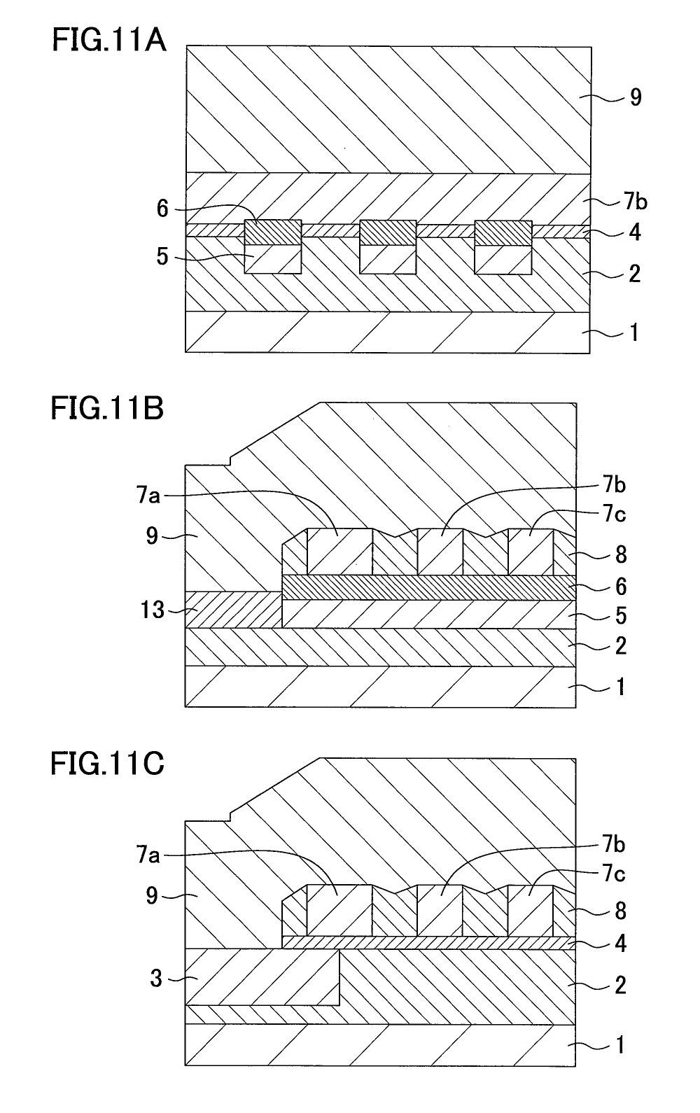

Next, as shown in FIGS. 11A-11C, the first interlayer insulating film 9 is formed on the isolation insulating film 3, the first, second, and third gate electrodes 7a, 7b, and 7c, the sidewall insulating film 8, and the contact diffusion layers 13. The first interlayer insulating film 9 is a silicon oxide film having a thickness of about 500 nm which is formed by CVD.

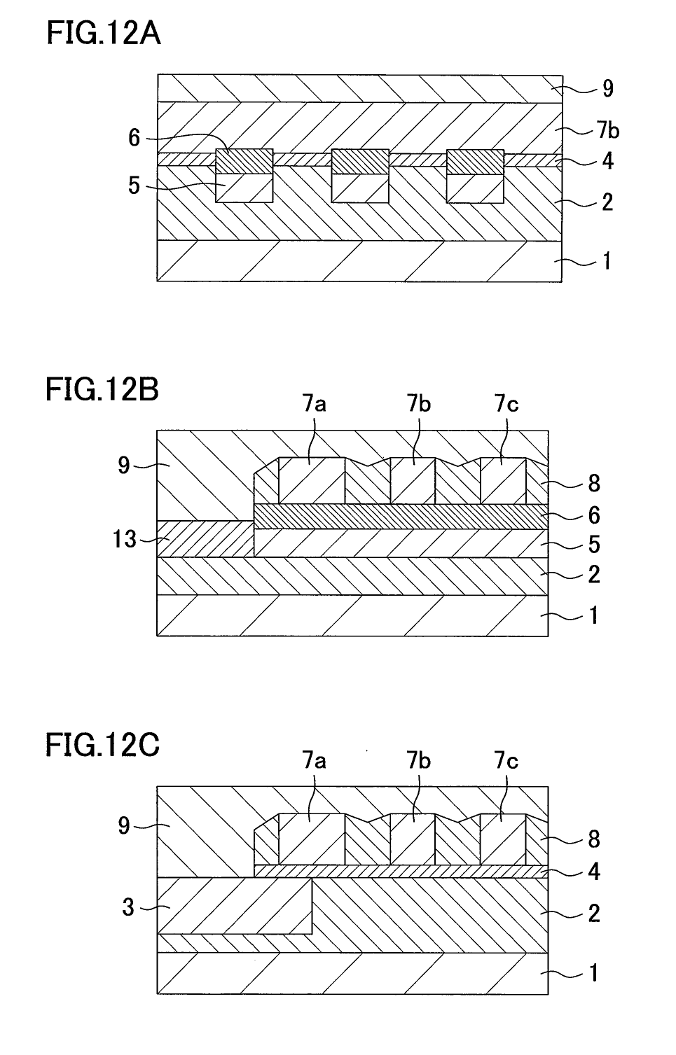

Next, as shown in FIGS. 12A-12C, an upper surface of the first interlayer insulating film 9 is planarized by chemical mechanical polishing (CMP).

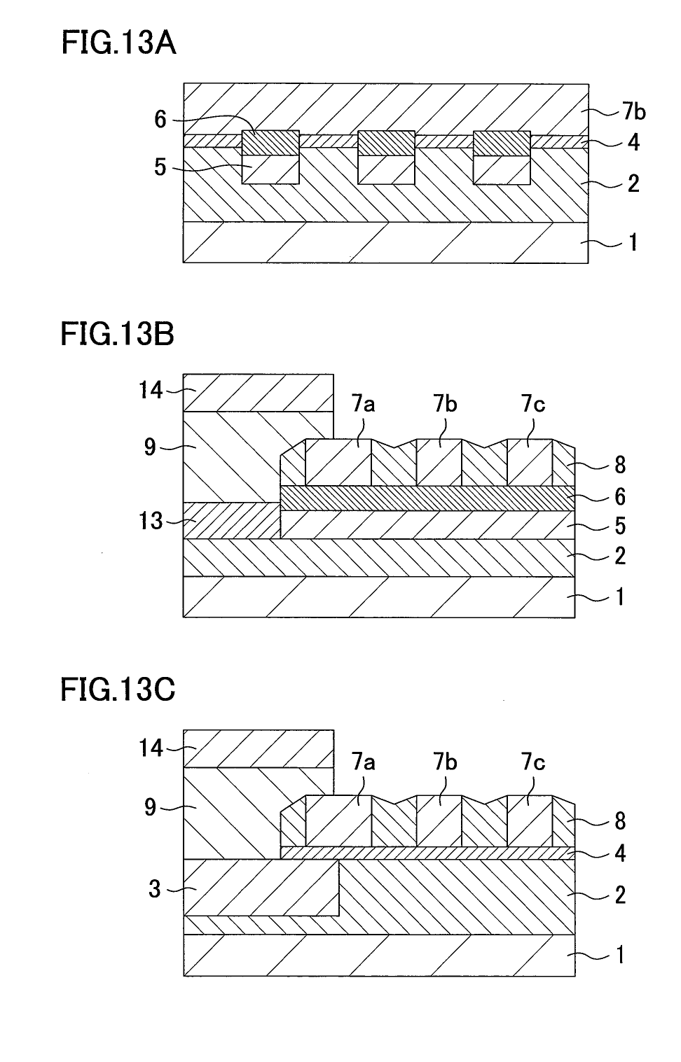

Next, as shown in FIGS. 13A-13C, a trench formation mask 16 provided on the first interlayer insulating film 9 is used to remove the first interlayer insulating film 9 in a memory cell region in which the word lines are formed, until the first, second, and third gate electrodes 7a, 7b, and 7c, and the sidewall insulating film 8 are exposed, thereby forming a trench. In this case, the mask 16 has an opening which allows an end portion of the trench in a direction in which the bit line diffusion layers 5 are extended, to be formed on the first gate electrode 7a.

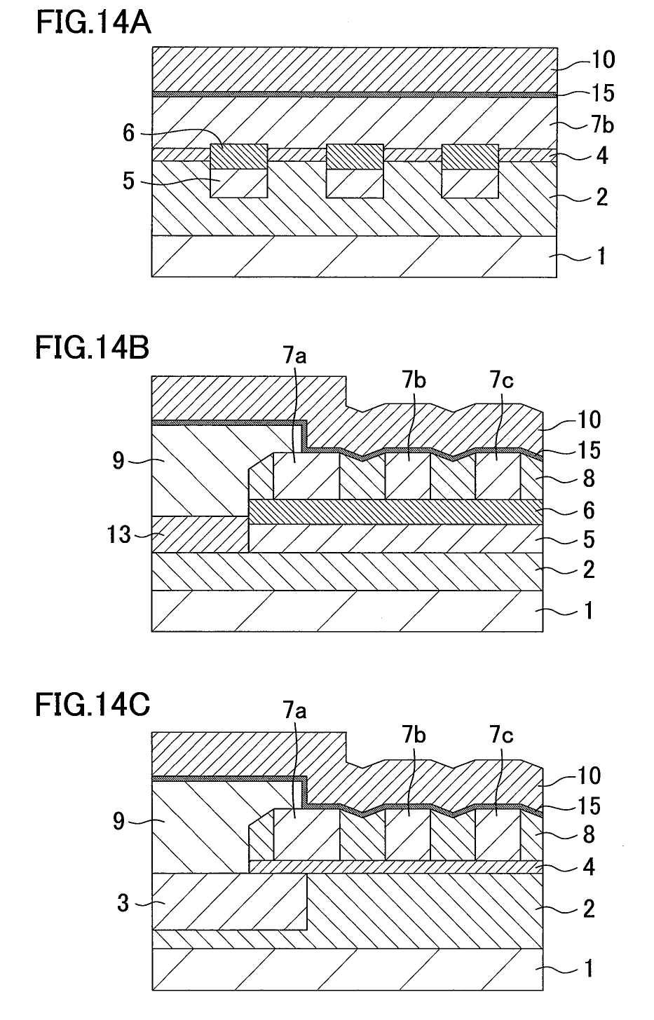

Next, as shown in FIGS. 14A-14C, after the mask 16 is removed, the liner insulating film 15 and the ultraviolet light blocking film 10 are successively formed to cover the first interlayer insulating film 9, and the first, second, and third gate electrodes 7a, 7b, and 7c, and the sidewall insulating film 8 in the trench. Here, the liner insulating film 15 preferably has a thickness of about 50 nm or less. This is because it is commonly considered that the wavelength of ultraviolet light which increases the threshold voltage of MONOS memory devices is about 250 nm, and the thickness of about 50 nm causes the influence of ultraviolet light on a memory cell to be small even if the diffraction and polarization of the light are taken into consideration. The liner insulating film 15 is a monolayer or multilayer film including one or at least two selected from SiO, SiN, SiC, SiCN, and SiOC. The ultraviolet light blocking film 10 is a monolayer or multilayer film including one or at least two selected from Si (including amorphous, polysilicon, and single crystal states, etc.), SiO, SiN, SiC, SiCN, SiOC, Ti, TiN, Al, Cu, and W. Films made of SiO or the like containing Si do not have perfect light blocking capability. In such films, the capability of blocking ultraviolet light is enhanced with an increase in the composition ratio of Si, i.e., the light blocking capability is adjusted by changing a thickness or the like thereof. Note that a monolayer film made of Si has almost perfect light blocking capability if the monolayer film has a thickness of about 60 nm. The ultraviolet light blocking film 10 may be doped with phosphorus (P), or may not be doped with phosphorus (P) when higher insulation capability is desired. A metal conductor, such as Ti, TiN, Al, Cu, W or the like, may be used if the conductor is allowed in terms of structure. In general, metal has high ultraviolet light blocking capability, and therefore, gold (Au), silver (Ag), platinum (Pt), or the like may be used. However, a metal film which is currently employed in commonly used semiconductor processes is illustrated herein.

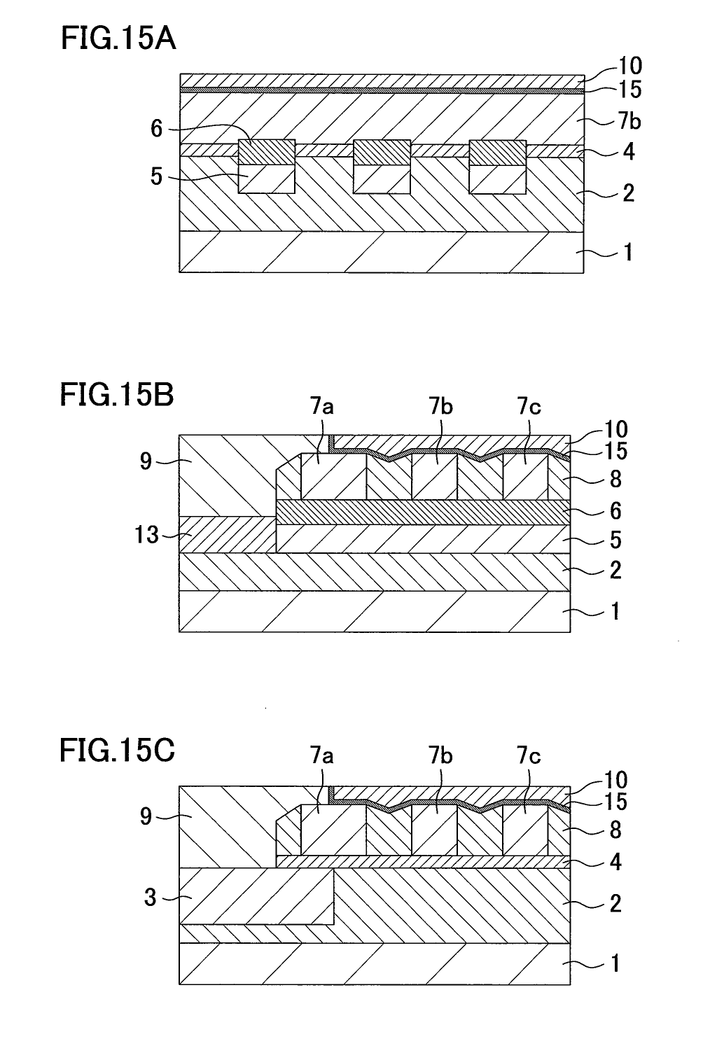

Next, as shown in FIGS. 15A-15C, the ultraviolet light blocking film 10 and the liner insulating film 15 are polished by CMP until the first interlayer insulating film 9 is exposed. Here, an upper portion of the ultraviolet light blocking film 10 may be further planarized to a thickness which allows the remaining ultraviolet light blocking film 10 to keep the light blocking capability.

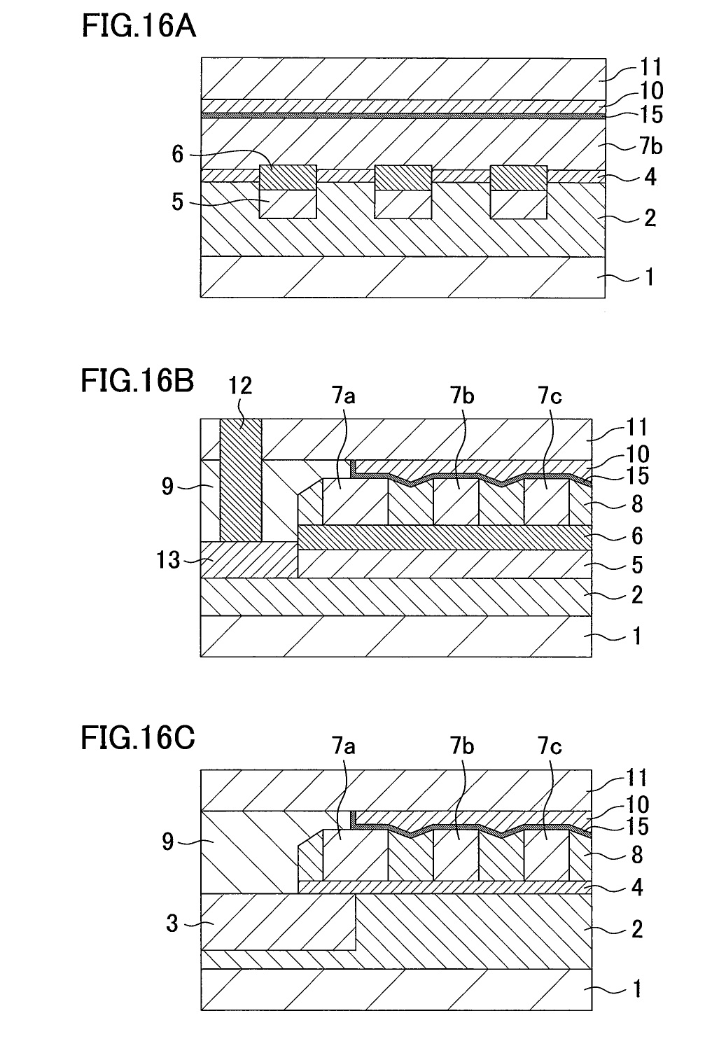

Next, as shown in FIGS. 16A-16C, the second interlayer insulating film 11 which is a silicon oxide film having a thickness of about 300 nm is formed, by CVD, on the first interlayer insulating film 9, the ultraviolet light blocking film 10, and the liner insulating film 15. Contact holes which penetrate the first interlayer insulating film 9 and the second interlayer insulating film 11 to expose the contact diffusion layers 13, are formed in regions in which the contact electrodes 12 are to be formed. A conductive film made of tungsten which is used to form the contact electrodes 12 is formed on the contact diffusion layers 13 and the second interlayer insulating film 11, to fill the contact holes. The conductive film formed on the second interlayer insulating film 11 is removed by CMP or etch-back, leaving the contact electrodes 12 only in the contact holes. Here, a barrier film made of titanium nitride may be formed in the contact holes before the contact electrodes 12 are formed.

Thereafter, the semiconductor memory device is completed by a wiring step following formation of a first-layer metal electrode. These steps are performed using commonly used techniques and therefore will not be described herein.

Although the ONO insulating film 4 is used as a trap insulating film in this illustrative embodiment, other structures may be used. For example, a high-k insulating film or the like may be used instead of the upper silicon oxide film.

The present disclosure is generally applicable to memory devices which are easily affected by ultraviolet light during fabrication. Examples of such memory devices include MONOS memory devices, which are the only memory devices that have been currently put into practical use. The present disclosure will be applicable to Si nano-dot memory devices, which are in the research stage and are considered to be similarly affected by ultraviolet light, if the devices are put into practical use.

In some fabrication methods, the isolation insulating film 3 may not be used, or the bit line insulating film 6 may be the ONO insulating film 4 itself.

The P-type well 2 may be an N-type well, the memory cell may be of PMOS type, and the bit line diffusion layers 5 and the contact diffusion layers 13 may be P-type diffusion layers.

A silicide structure may be formed in upper portions of the first, second, and third gate electrodes 7a, 7b, and 7c.

According to the method for fabricating the semiconductor memory device of the first illustrative embodiment, it is possible to reduce or eliminate the protrusion portion of the ultraviolet light blocking film which extends into the contact formation region, and it is possible to reduce or prevent ultraviolet light which enters in the horizontal direction through an end portion of the ultraviolet light blocking film and reaches the ONO insulating film which is to be the charge trapping film of a memory cell. As a result, the area of the contact region can be reduced, and in addition, the increase in the initial threshold voltage of the memory cell can be reduced or prevented, whereby a stable memory characteristic can be obtained.

### Second Illustrative Embodiment

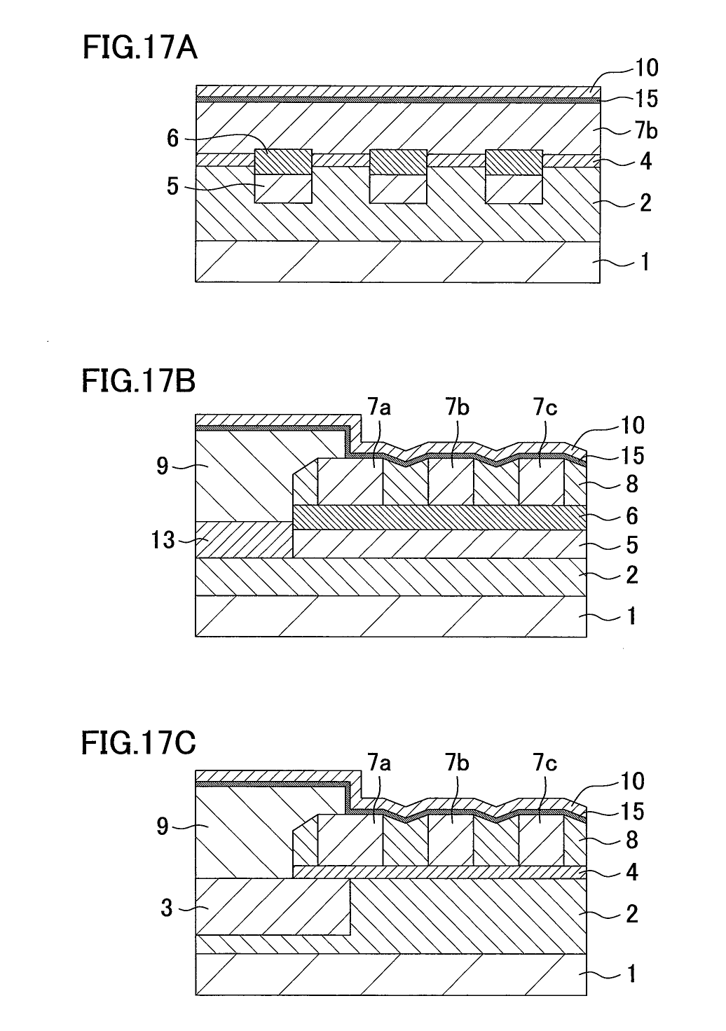

A method for fabricating a semiconductor memory device according to a second illustrative embodiment will be described hereinafter with reference to FIGS. 17A-21C.

Here, the semiconductor memory device of the second illustrative embodiment has the same structure as viewed from the top as that of the first illustrative embodiment of FIG. 1, and therefore, the structure as viewed from the top will not be described. In the second illustrative embodiment, steps earlier than one corresponding to a structure shown in FIG. 17 are the same as those of the first illustrative embodiment of FIGS. 7A-13C, and therefore, will not be described. The same components as those of the first illustrative embodiment are indicated by the same reference characters and will not be described. Those figures having a number followed by the capital letter “A” show cross-sectional structures of the device as viewed along line X1-X1 of FIG. 1 in the order in which the device is fabricated. Those figures having a number followed by the capital letter “B” show cross-sectional structures of the device as viewed along line Y1-Y1 of FIG. 1 in the order in which the device is fabricated. Those figures having a number followed by the capital letter “C” show cross-sectional structures of the device as viewed along line Y2-Y2 of FIG. 1 in the order in which the device is fabricated.

Initially, as shown in FIGS. 17A-17C, after the structure of the first illustrative embodiment shown in FIG. 13 has been formed, the liner insulating film 15 and the ultraviolet light blocking film 10 are successively formed to cover the first interlayer insulating film 9, and the first, second, and third gate electrodes 7a, 7b, and 7c, and the sidewall insulating film 8 in the trench. Here, the ultraviolet light blocking film 10 is formed so that the height of an upper surface of the ultraviolet light blocking film 10 formed in the trench is lower than the height of an upper surface of the first interlayer insulating film 9, except for a region in the vicinity of a sidewall of the trench.

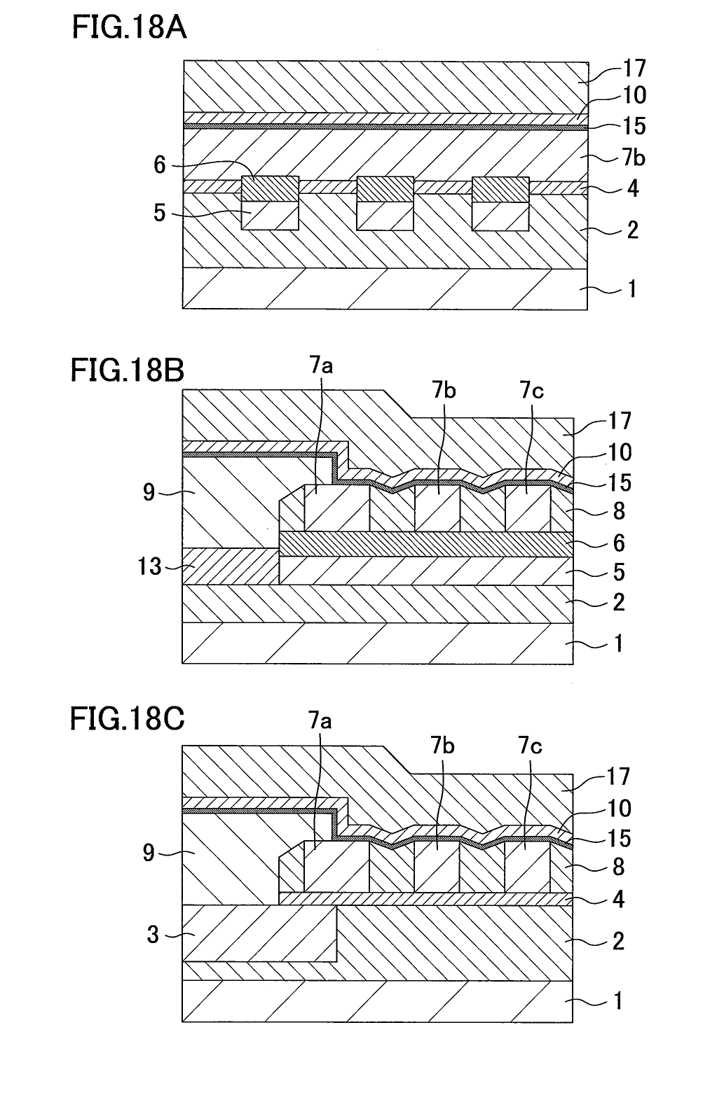

Next, as shown in FIGS. 18A-18C, a third interlayer insulating film 17 is formed on the ultraviolet light blocking film 10.

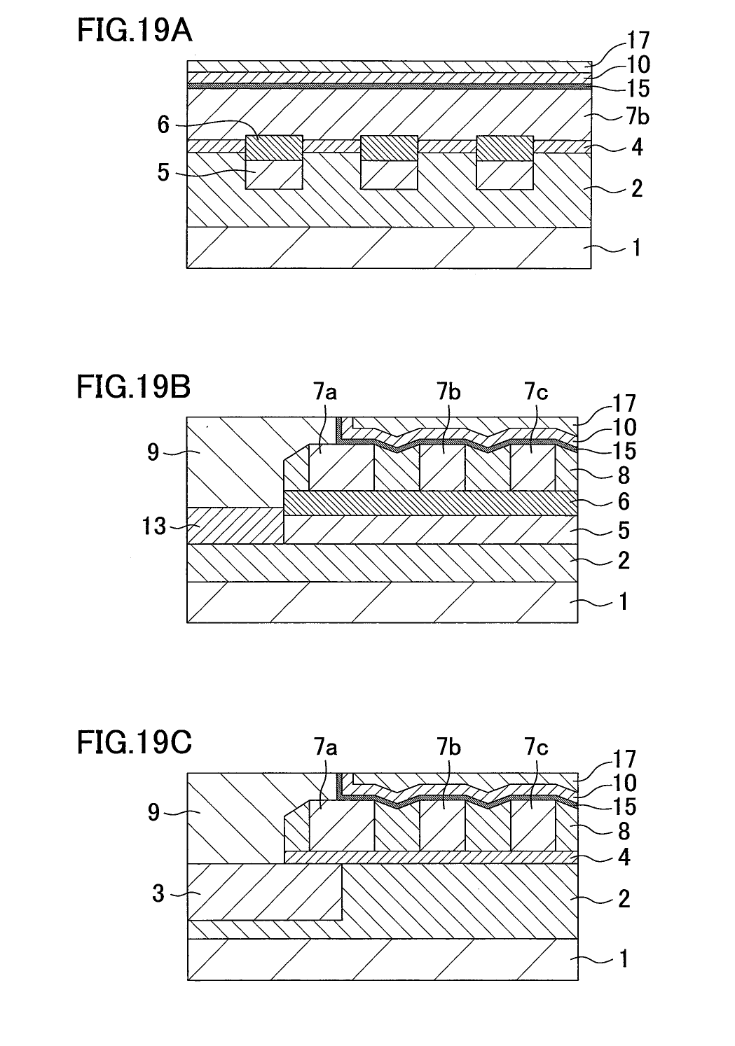

Next, as shown in FIGS. 19A-19C, portions of the third interlayer insulating film 17, the ultraviolet light blocking film 10, and the liner insulating film 15 are removed and planarized by CMP until the first interlayer insulating film 9 is exposed. In this case, the liner insulating film 15, the ultraviolet light blocking film 10, and a lower portion of the third interlayer insulating film 17 remain in the trench, and therefore, the ultraviolet light blocking film 10 covers the memory cell region.

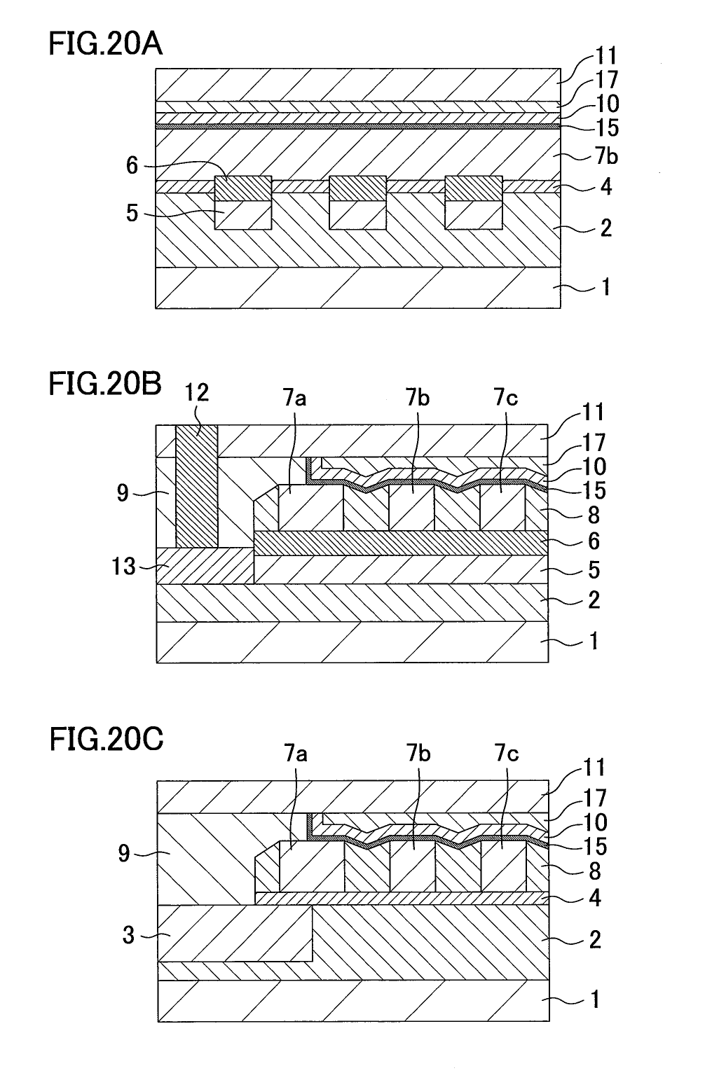

Next, as shown in FIGS. 20A-20C, the second interlayer insulating film 11 is formed on the first interlayer insulating film 9, the ultraviolet light blocking film 10, the liner insulating film 15, and the third interlayer insulating film 17. Contact holes which penetrate the first interlayer insulating film 9 and the second interlayer insulating film 11 to expose the contact diffusion layers 13 are formed in regions in which the contact electrodes 12 are to be formed, and a conductive film for forming the contact electrodes 12 is formed on the second interlayer insulating film 11 to fill the contact holes. The conductive film formed on the second interlayer insulating film 11 is removed by CMP or etch-back, leaving the contact electrodes 12 only in the contact holes. Here, a barrier film made of titanium nitride may be formed in the contact holes before the contact electrodes 12 are formed.

Thereafter, the semiconductor memory device is completed by a wiring step following formation of a first-layer metal electrode. These steps are performed using commonly used techniques and therefore will not be described herein.

According to the method for fabricating the semiconductor memory device of the second illustrative embodiment, it is possible to reduce or eliminate the protrusion portion of the ultraviolet light blocking film which extends into the contact formation region, and it is possible to reduce or prevent ultraviolet light which enters in the horizontal direction through an end portion of the ultraviolet light blocking film and reaches the ONO insulating film which is to be the charge trapping film of a memory cell. As a result, the area of the contact region can be reduced, and in addition, the increase in the initial threshold voltage of the memory cell can be reduced or prevented, whereby a stable memory characteristic can be obtained.

Moreover, the second illustrative embodiment can provide the following advantages in addition to those of the first illustrative embodiment.

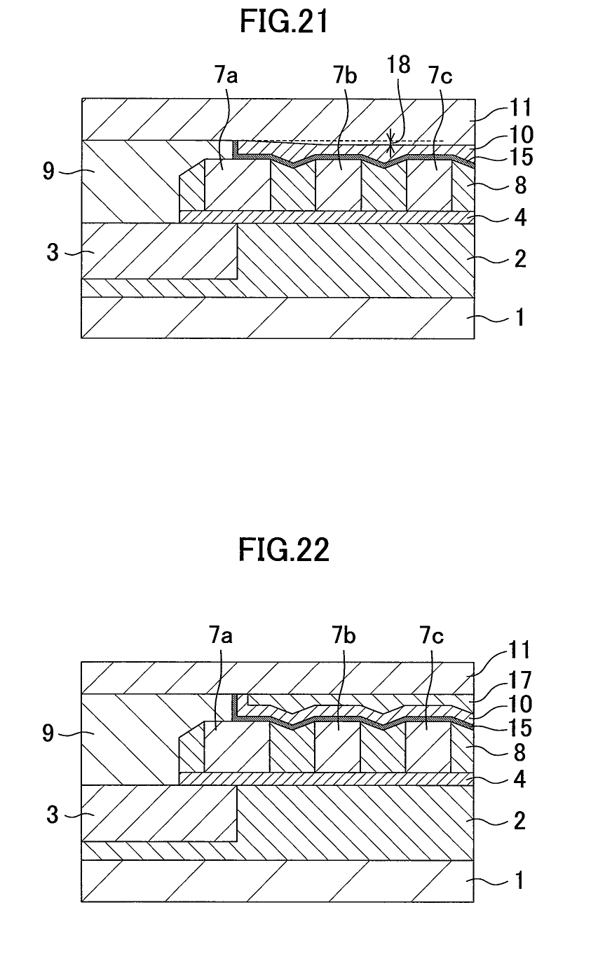

As shown in FIG. 21, in the first illustrative embodiment, dishing 18 may occur when the ultraviolet light blocking film 10 is subjected to CMP, likely leading to a reduction in the uniformity of the thickness of the ultraviolet light blocking film 10.

By contrast, as shown in FIG. 22, in the second illustrative embodiment, the height of the upper surface of the ultraviolet light blocking film 10 is lower than the height of the upper surface of the first interlayer insulating film 9 in the trench formed in the memory cell region, and therefore, the ultraviolet light blocking film 10 bends upwards on the dummy word line at a side end of the trench. In other words, in FIG. 19, most of the upper surface of the ultraviolet light blocking film 10 is covered with the third interlayer insulating film 17, and therefore, the dishing 18 does not occur in the ultraviolet light blocking film 10. As a result, the thickness of the ultraviolet light blocking film 10 has good uniformity. Therefore, the increase in the initial threshold voltage of the memory cell can be more effectively reduced or prevented, resulting in a stable memory characteristic.

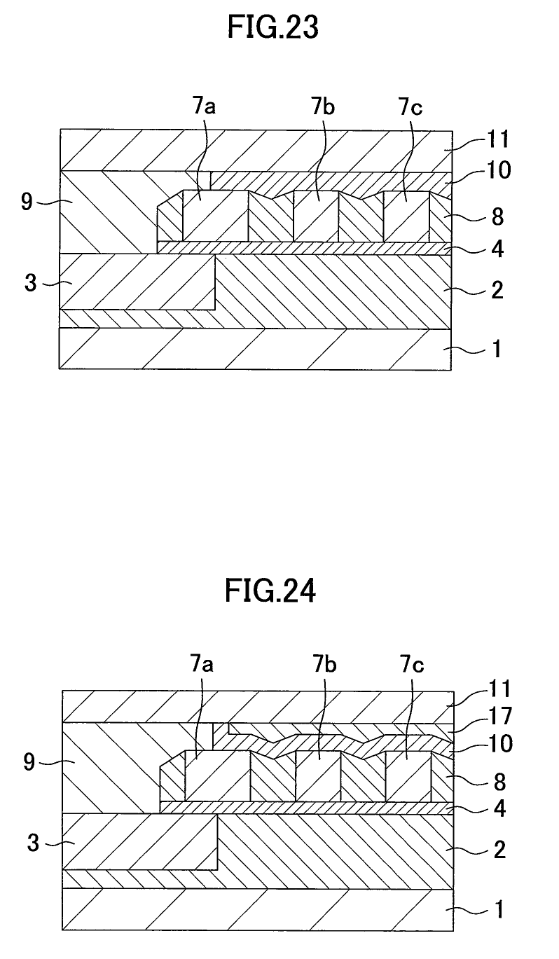

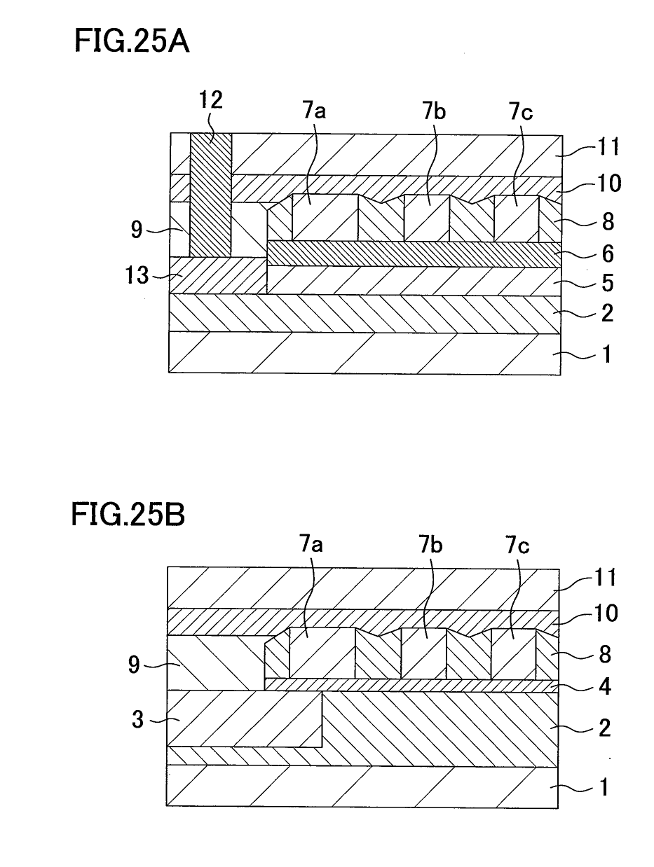

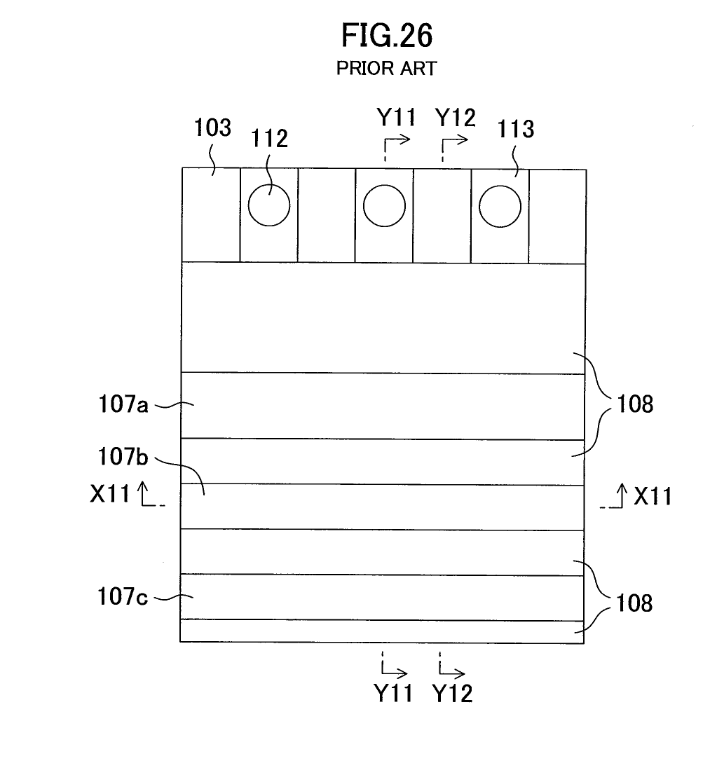

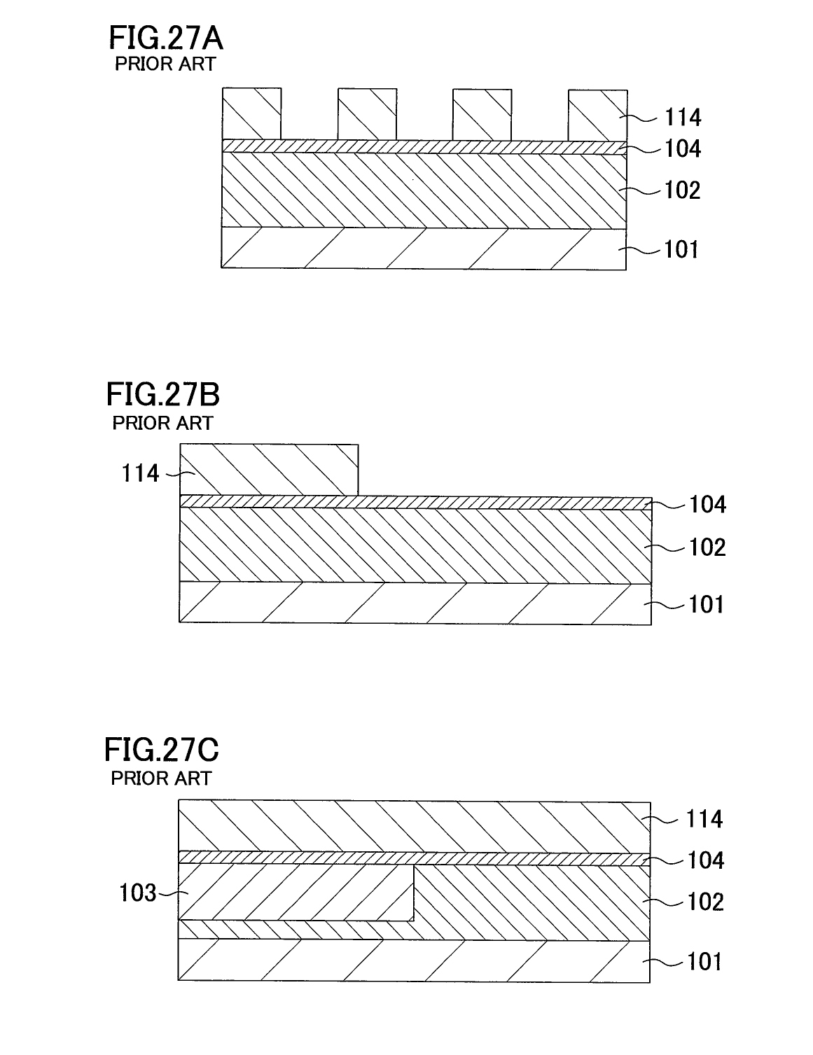

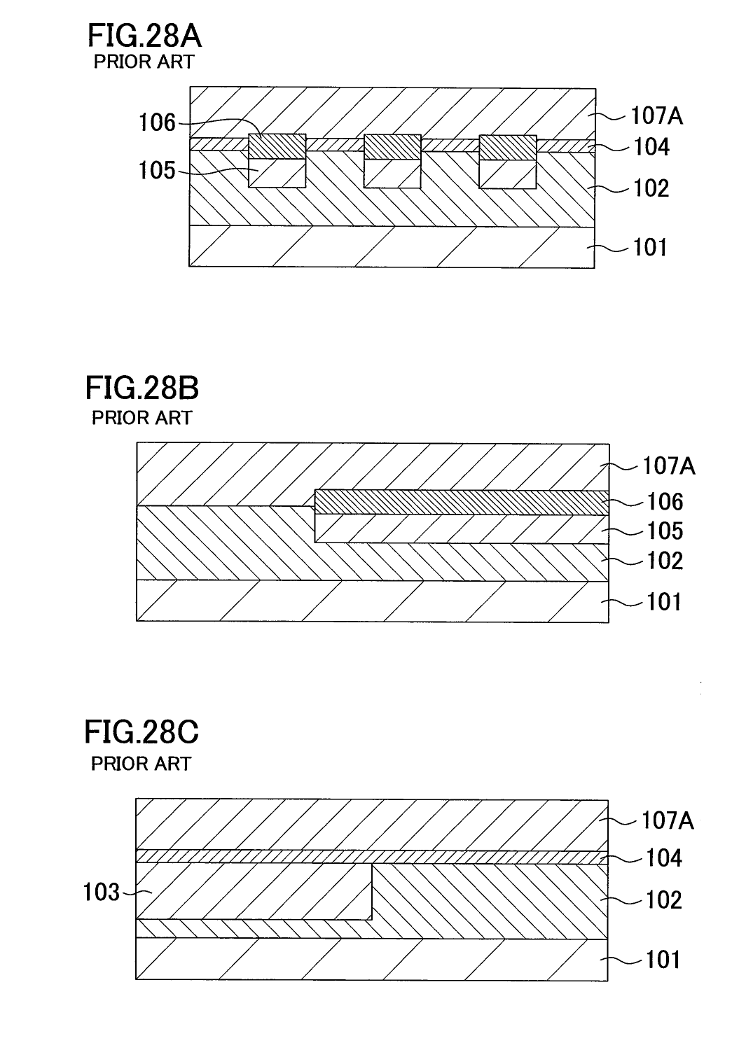

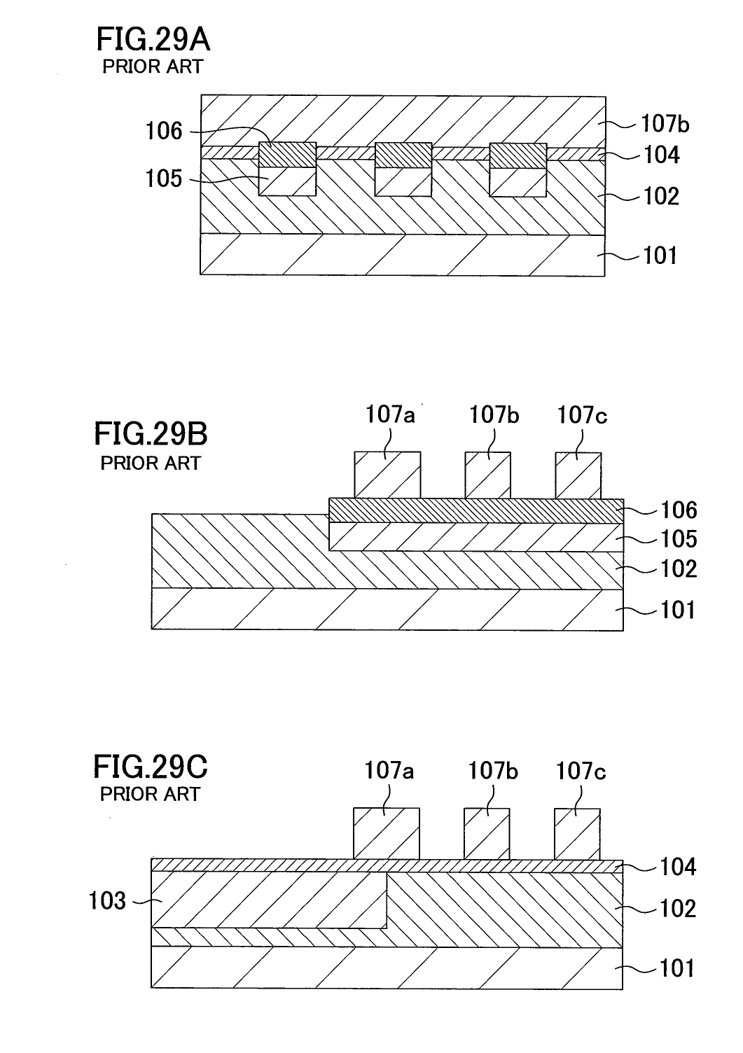

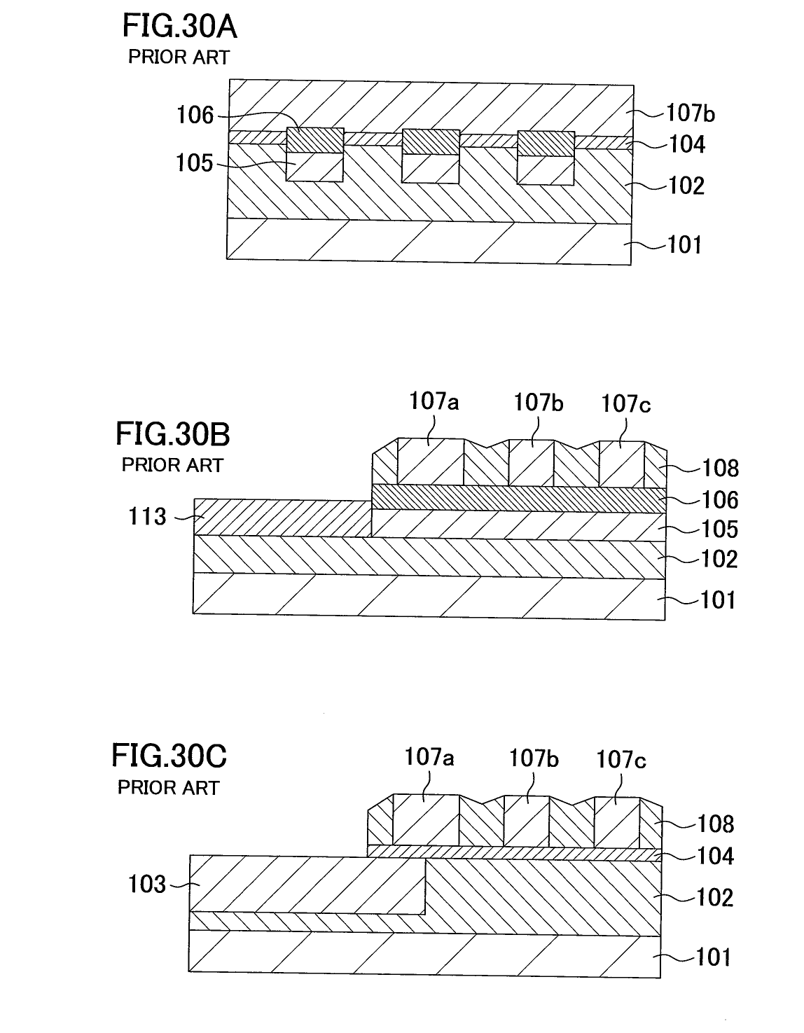

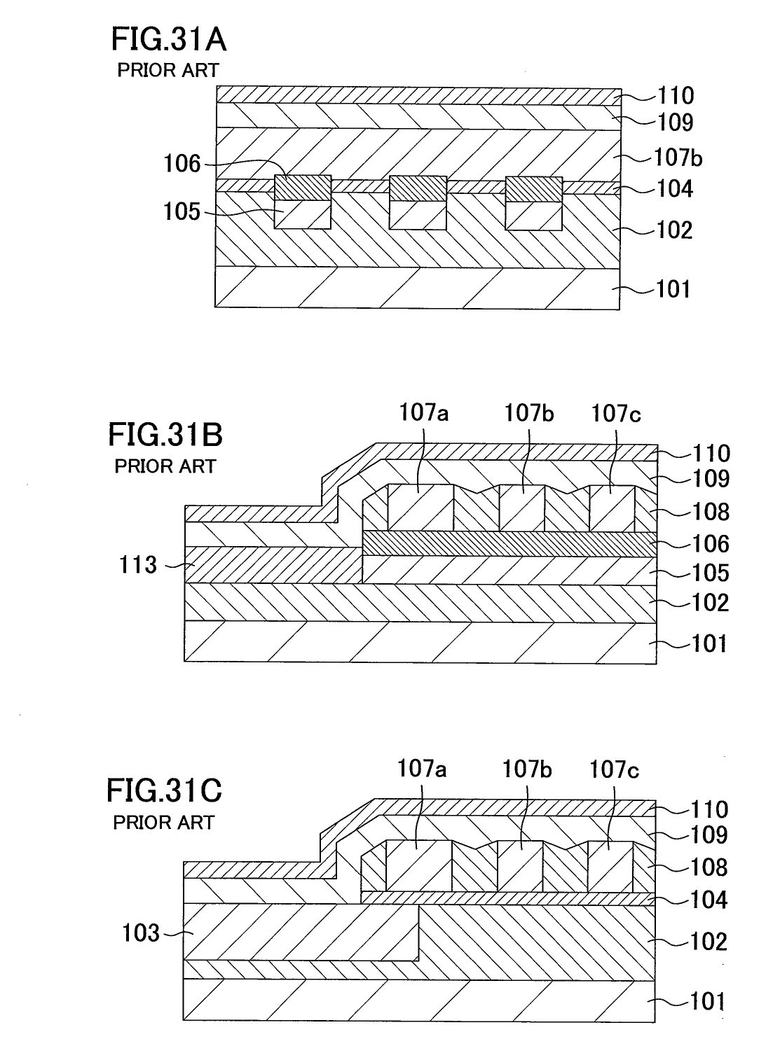

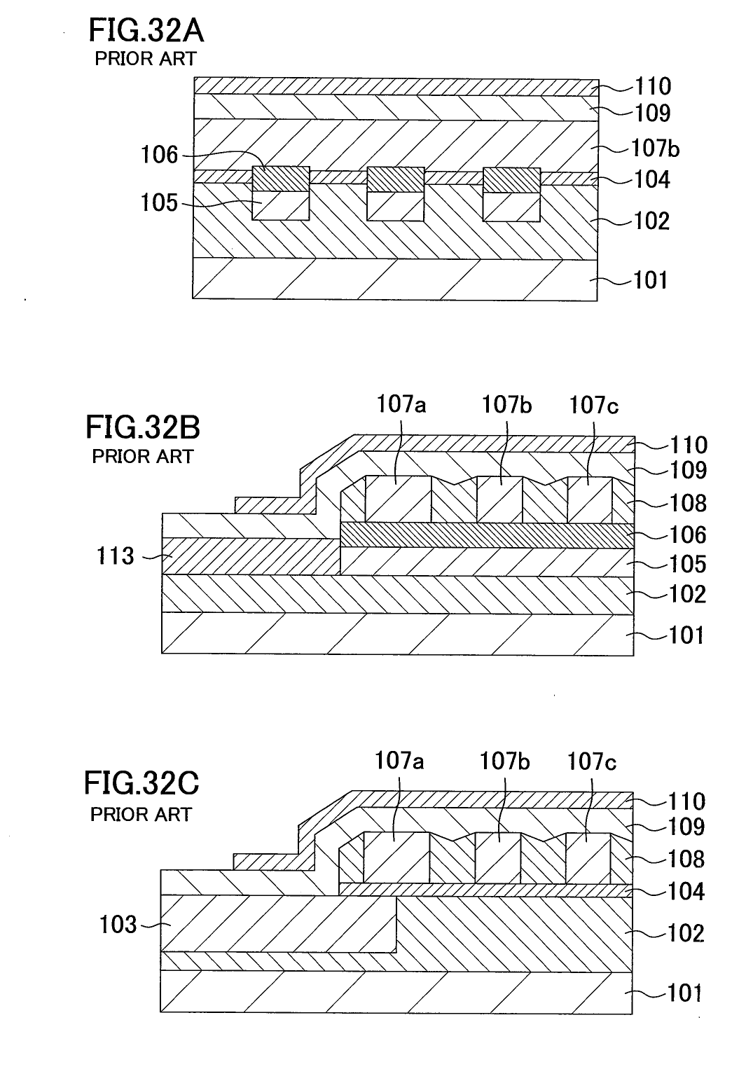

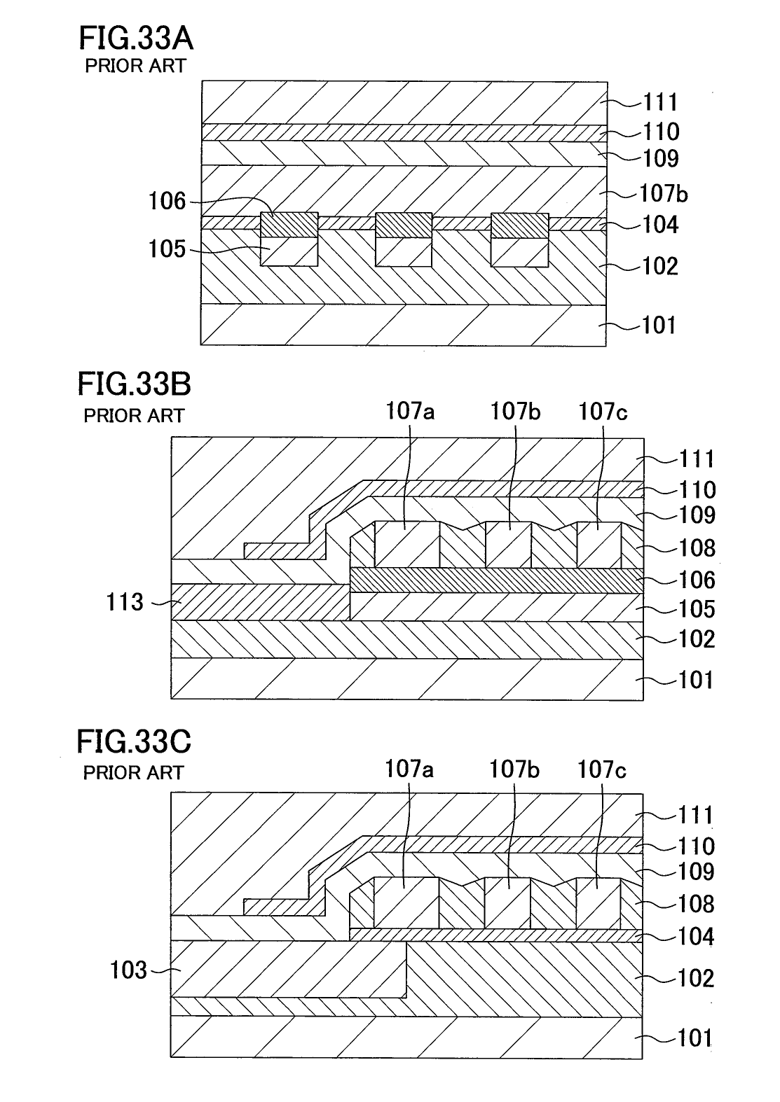

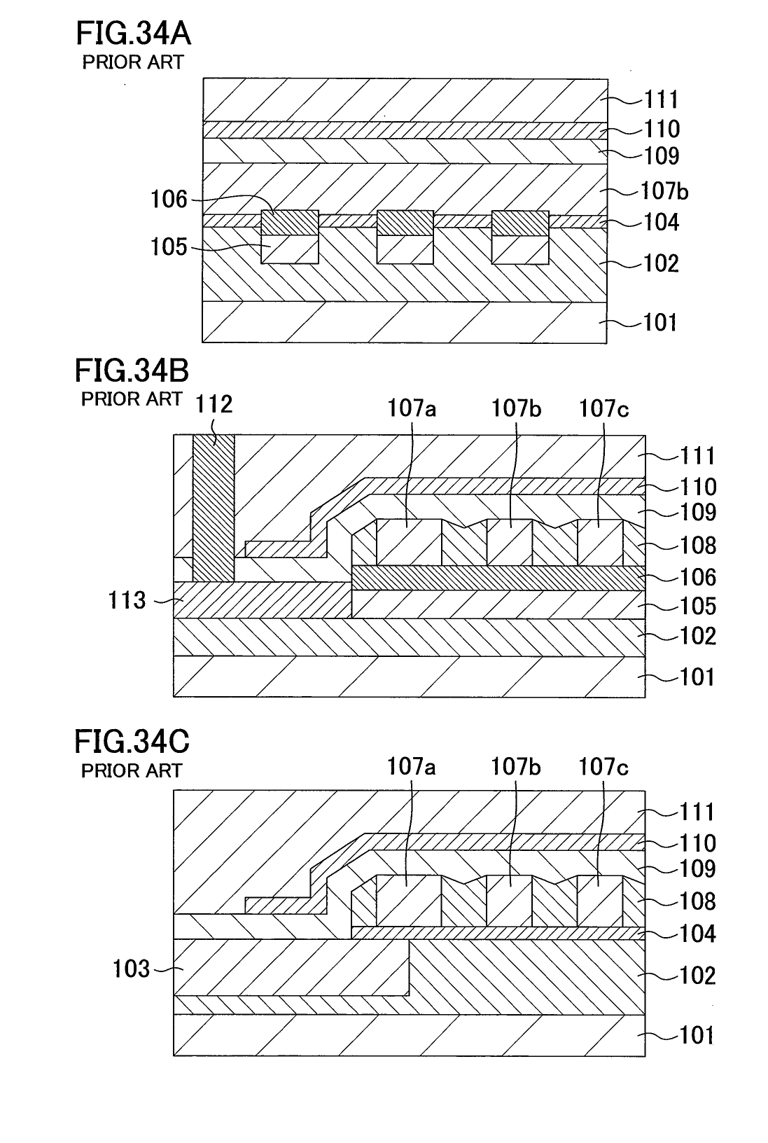

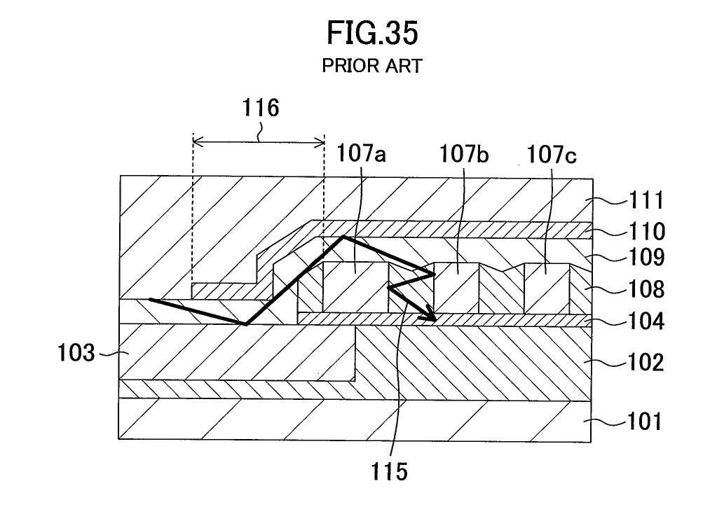

In the first and second illustrative embodiments, if an insulating film is employed as the ultraviolet light blocking film 10, then even when the ultraviolet light blocking film 10 is formed directly on the second and third gate electrodes 7b and 7c, which are to be word lines, as shown in FIGS. 23 and 24, the word lines do not cause a short circuit, and therefore, the liner insulating film 15 does not have to be formed. Moreover, as shown in FIG. 25, a trench may not be formed on the memory cell region, an upper portion of the first interlayer insulating film 9 may be removed until the first, second, and third gate electrodes 7a, 7b, and 7c are exposed, and the ultraviolet light blocking film 10 may be formed on the first interlayer insulating film 9, the first, second, and third gate electrodes 7a, 7b, and 7c, and the sidewall insulating film 8.

As described above, according to the method for fabricating the semiconductor memory device of the present disclosure, the area of the contact region can be reduced, and in addition, the increase in the initial threshold voltage of a memory cell can be reduced or prevented, whereby a stable memory characteristic can be obtained. Therefore, the present disclosure is particularly useful for methods for fabricating non-volatile semiconductor memory devices, and the like.

What is claimed is:

1. A method for fabricating a semiconductor memory device, comprising the steps of:
(a) forming a charge trapping film on a semiconductor substrate and removing a portion of the charge trapping film to form a plurality of openings which expose the semiconductor substrate;
(b) forming a plurality of bit line diffusion layers extending in a predetermined direction in parallel with each other, on the exposed semiconductor substrate;
(c) forming a plurality of word lines extending in parallel with each other and intersecting each of the plurality of bit line diffusion layers, on the charge trapping film and the plurality of bit line diffusion layers;
(d) forming a sidewall insulating film on side surfaces of the plurality of word lines to be embedded between any adjacent two of the plurality of word lines;
(e) forming a first interlayer insulating film to cover the charge trapping film, each of the plurality of bit line diffusion layers, each of the plurality of word lines, and the sidewall insulating film;
(f) forming a trench to expose the plurality of word lines and the sidewall insulating film by removing the first interlayer insulating film on a memory cell region in which the plurality of bit line diffusion layers and the plurality of word lines are formed; and
(g) forming an ultraviolet light blocking film on the plurality of word lines and the sidewall insulating film to fill the trench,
wherein
in step (f), the trench is formed so that an end of the trench in a direction in which the bit line diffusion layers are extended is located on the word line which is located at an outermost portion of the memory cell region.

2. The method of claim 1, further comprising the steps of:
(d1) between steps (d) and (e), forming a plurality of contact diffusion layers connected to the respective bit line diffusion layers, in regions of an upper portion of the semiconductor substrate extending from the respective bit line diffusion layers, using, as a mask, the word line and the sidewall insulating film located at an outermost portion of the memory cell region;
(h) after step (g), forming a second interlayer insulating film to cover the first interlayer insulating film and the ultraviolet light blocking film; and
(i) after step (h), forming, on the respective contact diffusion layers, contact electrodes which penetrate the second interlayer insulating film and the first interlayer insulating film to connect to the respective contact diffusion layers.

3. The method of claim 1, further comprising the step of:
(f1) between steps (f) and (g), forming an insulating film on a bottom surface and a sidewall of the trench,
wherein
in step (g), the ultraviolet light blocking film is formed on the insulating film.

4. The method of claim 1, further comprising the step of:
(g1) after step (g), forming a third interlayer insulating film on the ultraviolet light blocking film,
wherein
the third interlayer insulating film is formed to fill the trench.

5. The method of claim 4, further comprising the steps of:
(d1) between steps (d) and (e), forming a plurality of contact diffusion layers connected to the respective bit line diffusion layers, in regions of an upper portion of the semiconductor substrate extending from the respective bit line diffusion layers, using, as a mask, the word line and the sidewall insulating film located at an outermost portion of the memory cell region;
(h1) after step (g1), forming a second interlayer insulating film to cover the first interlayer insulating film, the ultraviolet light blocking film, and the third interlayer insulating film; and
(i) after step (h1), forming, on the respective contact diffusion layers, contact electrodes which penetrate the second interlayer insulating film and the first interlayer insulating film to connect to the respective contact diffusion layers.

6. The method of claim 4, further comprising the step of:
(f1) between steps (f) and (g), forming an insulating film on a bottom surface and a sidewall of the trench,
wherein
in step (g), the ultraviolet light blocking film is formed on the insulating film.

7. The method of claim 1, wherein
the word line located at the outermost portion of the memory cell region is a dummy word line.

8. The method of claim 3, wherein
the insulating film is a monolayer or multilayer film including one or at least two selected from a silicon oxide film, a silicon nitride film, a silicon carbide film, a silicon carbon nitride film, and a silicon oxycarbide film.

9. The method of claim 3, wherein
the insulating film has a thickness of 5 nm or more and 50 nm or less.

10. The method of claim 1, wherein
the ultraviolet light blocking film is a monolayer or multilayer film including one or at least two selected from a silicon film, a silicon oxide film, a silicon nitride film, a silicon carbide film, a silicon carbon nitride film, a silicon oxycarbide film, a titanium film, a titanium nitride film, an aluminum film, a copper film, and a tungsten film.
